(19) United States
(12) Patent Application Publication
(10) Pub. No.: US 2026/0099407 A1
(43) Pub. Date: Apr. 9, 2026

(54) OPERATING METHOD OF NON-VOLATILE MEMORY DEVICE, STORAGE DEVICE, AND OPERATING METHOD OF STORAGE DEVICE

(71) Applicant: SAMSUNG ELECTRONICS CO., LTD., Suwon-si (KR)

(72) Inventors: Minki Song, Suwon-si (KR); Daeyeol Yang, Suwon-si (KR); Bohwan Jun, Suwon-si (KR); Shihye Kim, Suwon-si (KR); Ikkyun Park, Suwon-si (KR); Dongmin Shin, Suwon-si (KR); Hyunju Yi, Suwon-si (KR)

(21) Appl. No.: 19/202,950

(22) Filed: May 8, 2025

(30) Foreign Application Priority Data
Oct. 8, 2024 (KR) 10-2024-0136799

(51) Int. Cl. G06F 11/10

(52) U.S. Cl. CPC G06F 11/1068; G06F 11/1004; G06F 11/1016

(57) ABSTRACT

An operating method of a storage device includes transmitting, by a storage controller, data and the transmission parity data to the non-volatile memory with respect to each data line, performing a counting operation, by a non-volatile memory, to count a number of transmission error bits with respect to each data line in a first group, based on first transmission parity data, performing a determination operation, by the non-volatile memory, to determine whether there is a transmission error with respect to each data line in a second group, based on second transmission parity data, determining, by the non-volatile memory, whether a condition for performing retraining is satisfied, based on a counting result generated from the counting operation and a determination result generated from the determination operation, and transmitting, by the non-volatile memory, transmission error status information to the storage controller when the condition for performing retraining is satisfied.

### CROSS-REFERENCE TO RELATED APPLICATION(S)

This application is based on and claims priority under 35 U.S.C. § 119 to Korean Patent Application No. 10-2024-0136799, filed on Oct. 8, 2024, in the Korean Intellectual Property Office, the disclosure of which is incorporated by reference herein in its entirety.

### BACKGROUND

Semiconductor memory is classified into volatile memory, such as static random access memory (SRAM) or dynamic RAM (DRAM), which loses data stored therein when power supply thereto is interrupted, and non-volatile memory, such as flash memory, phase-change RAM (PRAM), magnetic RAM (MRAM), resistive RAM (RRAM), or ferroelectric RAM (FRAM), which retains data stored therein even after power supply thereto is interrupted.

A storage device may include a controller to control non-volatile memory and volatile memory. Communication between a non-volatile memory and a controller can be performed at a lower operating frequency than a memory system including high-speed memory, such as DRAM or SRAM. However, in some situations, communication between non-volatile memory and a controller may be required to be performed at a high operating frequency. Therefore, various methods for communication signal alignment between non-volatile memory and a controller have been introduced.

### SUMMARY

The present disclosure provides an operating method of non-volatile memory, a storage device, and an operating method of the storage device.

According to an aspect of the present disclosure, an operating method of a storage device includes a storage controller and a non-volatile memory. The operating method includes generating, by the storage controller, a plurality of pieces of transmission parity data respectively corresponding to a plurality of data lines, the plurality of pieces of transmission parity data including first transmission parity data and second transmission parity data, transmitting, by the storage controller, a plurality of pieces of data respectively corresponding to the plurality of data lines and the plurality of pieces of transmission parity data respectively corresponding to the plurality of pieces of data to the non-volatile memory, the first transmission parity data being transmitted through a first group of data lines among the plurality of data lines, and the second transmission parity data being transmitted through a second group of data lines among the plurality of data lines, performing a counting operation, by the non-volatile memory, to count a number of transmission error bits with respect to each of the data line in the first group, based on the first transmission parity data, performing a determination operation, by the non-volatile memory, to determine whether there is a transmission error with respect to each of the data lines in the second group, based on the second transmission parity data, determining, by the non-volatile memory, whether a condition for performing retraining is satisfied, based on a counting result generated from the counting operation and a determination result generated from the determination operation, and transmitting, by the non-volatile memory, transmission error status information to the storage controller when the condition for performing retraining is satisfied.

According to another aspect of the present disclosure, an operating method includes receiving, from a storage controller, a plurality of pieces of data respectively corresponding to a plurality of data lines and a plurality of pieces of transmission parity data respectively corresponding to the plurality of pieces of data, performing a counting operation to count a number of transmission error bits with respect to each of the plurality of data lines, based on the transmission parity data, determining whether a condition for performing retraining is satisfied, based on a counting result generated from the counting operation, and transmitting transmission error status information to the storage controller when the condition for performing retraining is satisfied.

According to a further aspect of the present disclosure, a storage device includes a non-volatile memory and a storage controller configured to generate a plurality of pieces of transmission parity data respectively corresponding to a plurality of data lines and transmit, to the non-volatile memory, a plurality of pieces of data respectively corresponding to the plurality of data lines and the plurality of pieces of transmission parity data respectively corresponding to the plurality of pieces of data, wherein the non-volatile memory is configured to perform a counting operation to count a number of transmission error bits with respect to each of the plurality of data lines, based on the transmission parity data, determine whether a condition for performing retraining is satisfied, based on a counting result generated from the counting operation, and transmit transmission error status information to the storage controller when the condition for performing retraining is satisfied.

### BRIEF DESCRIPTION OF THE DRAWINGS

Implementations will be more clearly understood from the following detailed description taken in conjunction with the accompanying drawings in which:

FIG. 1 is a block diagram of a storage device according to an implementation;

FIG. 2 is a detailed block diagram of the storage device of FIG. 1;

FIG. 3 is a detailed block diagram of a storage controller in FIG. 1;

FIG. 4 is a detailed block diagram of a non-volatile memory in FIG. 1;

FIG. 5 is a detailed block diagram illustrating the storage controller and the non-volatile memory in FIG. 1, according to an implementation;

FIG. 6 is a detailed block diagram illustrating an error detection circuit and a retraining decision circuit in FIG. 4, according to an implementation;

FIG. 7 is a detailed block diagram illustrating an error detection circuit and a retraining decision circuit in FIG. 4, according to an implementation;

FIG. 8 is a block diagram illustrating an encoder included in a memory controller and a 1^{st}-X decoder included in an error counting circuit, according to an implementation;

FIGS. 9 to 11 are diagrams illustrating shortened Hamming code encoding;

FIGS. 12 to 14 are diagrams illustrating shortened Bose-Chaudhuri-Hocquenghem (BCH) code encoding;

FIG. 15 is a flowchart of an example of operation of the storage device of FIG. 1; and

FIG. 16 shows examples of a condition for performing retraining, according to an implementation.

### DETAILED DESCRIPTION

Implementations will be described in detail hereinafter so as to be easily implemented by one of ordinary skill in the art to which the present disclosure belongs.

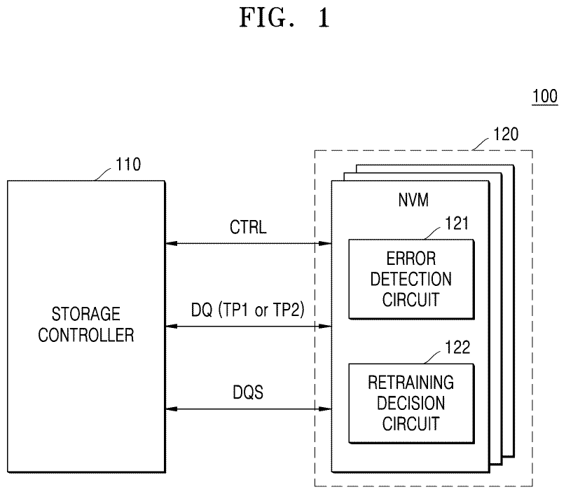

FIG. 1 is a block diagram of a storage device 100 according to an implementation.

Referring to FIG. 1, the storage device 100 may include a storage controller 110 and a non-volatile memory (NVM) device 120. In an implementation, the storage device 100 may include a mass storage medium such as a solid-state drive (SSD). The storage device 100 may be included in one of information processing devices, such as a personal computer (PC), a laptop computer, a server, a workstation, a smartphone, a tablet PC, a digital camera, and a black box, which are configured to process various types of information and store the processed information. However, implementations are not limited thereto, and the storage device 100 may be implemented in various forms and may be included in various types of devices or systems.

The storage controller 110 may be configured to control the NVM device 120. For example, the storage controller 110 may store data in the NVM device 120 or read data from the NVM device 120 under control by an external host. In an implementation, the storage controller 110 may perform various maintenance operations to increase the performance or reliability of the NVM device 120, regardless of control by an external host.

In an implementation, the storage controller 110 may be configured to communicate with the NVM device 120 through a predetermined memory interface. The predetermined memory interface may include at least one of various flash memory interfaces such as a toggle NAND interface and an open NAND flash interface (ONFI).

For example, to control the NVM device 120, the storage controller 110 may exchange various signals with the NVM device 120 through control signal lines CTRL, data lines DQ, and a data strobe line DQS.

For example, signals of the control signal line CTRL, the data strobe line DQS, and the data lines DQ may be provided to the NVM device 120 through different signal lines or different signal pins. A signal of the control signal line CTRL and a signal of the data strobe line DQS may be provided to identify signals (e.g., a command CMD, an address ADDR, and data), which are provided to the NVM device 120 through signals of the data lines DQ. For example, a signal of a data line DQ may refer to a signal transmitted and received through a data pin (or a DQ pin), and a signal of the data strobe line DQS may refer to a signal transmitted and received through a data strobe pin (or a DQS pin).

The NVM device 120 may operate under control by the storage controller 110. For example, the NVM device 120 may store data therein or output data stored therein under control by the storage controller 110. The NVM device 120 may include a plurality of NVMs.

For example, an NVM may identify whether a signal provided through signals of the data lines DQ is the command CMD, the address ADDR, or data, based on signals of the control signal lines CTRL. In an implementation, various signals, such as a command latch enable signal CLE, an address latch enable signal ALE, a read enable signal RE/, and a write enable signal WE/, may be provided to the NVM through the control signal lines CTRL.

The NVM may be configured to identify (or capture) data provided through signals of the data lines DQ, based on a signal of the data strobe line DQS. The NVM may store the identified data, based on the command CMD and the address ADDR.

For example, the NVM device 120 may include NAND flash memory. However, the present disclosure is not limited thereto. The NVM device 120 may include at least one of volatile or non-volatile memories, such as static random access memory (SRA M), dynamic RAM (DRAM), synchronous DRAM (SDRAM), read-only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), and ferroelectric RAM (FRAM).

The storage device 100 may perform training (e.g., read training or write training) to increase the accuracy of communication when performing every function. The storage device 100 may determine the alignment of signals of the data lines DQ and the target delay of a signal of the data strobe line DQS. As the speed of data input/output between the storage controller 110 and the NVM increases, retraining is required.

The NVM and the storage controller 110 may exchange data with each other through the data lines DQ. A delay on the path of the data lines DQ and the data strobe line DQS may vary with a temperature change. When sampling timing varies with a delay change, a setup/hold margin may decrease. The storage controller 110 may perform retraining to compensate for a delay change involved in a temperature change. Accordingly, the storage controller 110 may adjust a delay on a path. However, when retraining is performed, resources used for training may increase.

For example, the storage controller 110 may periodically collect temperature information or voltage information with respect to each of the NVMs. The storage controller 110 may periodically transmit an oscillator request command to the NVMs. The storage controller 110 may periodically request an oscillator value (e.g., a frequency or timing value) of a data strobe signal. The storage controller 110 may perform a monitoring operation on each of the NVMs. The monitoring operation may include an operation of monitoring a delay change on a path of the data lines DQ and the data strobe line DQS. The storage controller 110 may determine the retraining timing of each NVM through the monitoring operation. Accordingly, the performance of the storage device 100 may degrade.

According to an implementation, the storage device 100 may determine a retraining timing while performing a normal operation. For example, the storage device 100 may determine a retraining timing through a write operation, without a monitoring operation. Alternatively, the storage device 100 may determine a retraining timing through a monitoring operation and a write operation.

The storage controller 110 may generate transmission parity data for each of the data lines DQ. The storage controller 110 may transmit transmission parity data together with data to an NVM. In an implementation, the storage controller 110 may transmit data, memory parity data, and a transmission parity data to the NVM.

Here, the memory parity data may refer to parity data used to improve memory cell reliability. The transmission parity data may refer to parity data used to improve transmission error.

The transmission parity data may correspond to first transmission parity data TP1 or second transmission parity data TP2.

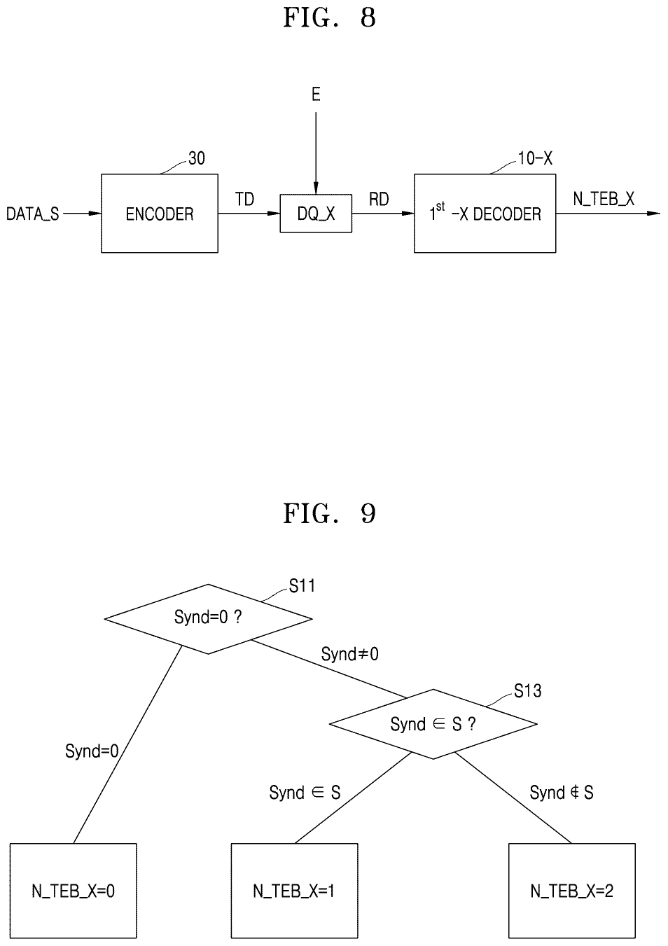

Here, the first transmission parity data TP1 may refer to parity data, which is transmitted from the storage controller 110 to the NVM through each of the data lines DQ and used by the NVM to count the number of error bits resulting from transmission errors on a given data line. The first transmission parity data TP1 will be described in detail with reference to FIGS. 8 to 14.

The second transmission parity data TP2 may refer to parity data, which is transmitted from the storage controller 110 to the NVM through each of the data lines DQ and used by the NVM to determine whether there is a transmission error on a given data line. For example, the second transmission parity data TP2 may correspond to a cyclic redundancy check (CRC) value of transmitted data.

Here, according to the purpose and scope of error detection, the first transmission parity data TP1 and the second transmission parity data TP2 may be transmitted through the same data line, or the first transmission parity data TP1 or the second transmission parity data TP2 may be transmitted through multiple data lines DQ so that the first transmission parity data TP1 or the second transmission parity data TP2 is transmitted through each data line without overlap. Alternatively, the first transmission parity data TP1 or the second transmission parity data TP2 may be transmitted through each of the data lines DQ.

Hereinafter, an error bit resulting from transmission error per codeword on a data line is referred to as a transmission error bit.

The NVM may perform transmission error detection based on transmission parity data. The NVM may also determine whether a condition for performing retraining is satisfied, based on a result of the transmission error detection.

In an implementation, transmission parity data may correspond to the first transmission parity data TP1. The NVM may count the number of transmission error bits with respect to each of the data lines DQ, based on the first transmission parity data TP1. The NVM may also determine whether a condition for performing retraining is satisfied, based on a counting result generated from the counting operation.

In some implementations, transmission parity data may correspond to the second transmission parity data TP2. The NVM may determine whether there is a transmission error on each of the data lines DQ, based on the second transmission parity data TP2. The NVM may also determine whether a condition for performing retraining is satisfied, based on a determination result generated from the determination operation.

In some implementations, transmission parity data may include the first transmission parity data TP1 and the second transmission parity data TP2. In other words, a first group of pieces of transmission parity data may correspond to the first transmission parity data TP1, and a second group of pieces of transmission parity data may correspond to the second transmission parity data TP2. Here, a first group of data lines DQ may transmit the first transmission parity data TP1 corresponding to the first group from the storage controller 110 to the NVM, and a second group of data lines DQ may transmit the second transmission parity data TP2 corresponding to the second group from the storage controller 110 to the NVM. The NVM may count the number of transmission error bits on each of the data lines DQ in the first group, based on the first transmission parity data TP1. The NVM may determine whether there is a transmission error on each of the data lines DQ in the second group, based on the second transmission parity data TP2. The NVM may determine whether a condition for performing retraining is satisfied, based on a counting result generated from the counting operation and a determination result generated from the determination operation.

When the NVM determines that retraining is not required, based on a result of transmission error detection, the NVM may perform a write operation of received data.

When the NVM determines that retraining is required, based on a result of transmission error detection, the NVM may provide transmission error status information to the storage controller 110. Here, the transmission error status information may refer to information about an error that has occurred during data transmission through a data line and may include whether to perform retraining on all the data lines DQ, whether to perform retraining on each of the data lines DQ, or the number of transmission error bits on each data line. In this case, the NVM may not perform a write operation on the received data.

The NVM may provide transmission error status information to the storage controller 110, in response to a status read command of the storage controller 110. Here, the status read command may be referred to as a get-feature command.

In an implementation, the NVM may provide the storage controller 110 with the transmission error status information corresponding to whether retraining of all the data lines DQ is required. In other words, the NVM may determine whether retraining of all the data lines DQ is required. For example, the transmission error status information may be represented by one bit and may indicate a transmission error status (a pass or a fail) of all the data lines DQ. For example, when the transmission error status of all the data lines DQ is a pass, the NVM may transmit the transmission error status information corresponding to “1” to the storage controller 110. When the transmission error status of all the data lines DQ is a fail, the NVM may transmit the transmission error status information corresponding to “0” to the storage controller 110.

In some implementations, the NVM may provide the storage controller 110 with the transmission error status information, which corresponds to whether retraining of each of the data lines DQ is required or the number of transmission error bits on each of the data lines DQ. In other words, the NVM may determine whether retraining is required for each data line or may count the number of transmission error bits on each of the data lines DQ. For example, the NVM may provide the storage controller 110 with transmission error status information represented by two or more bits. Here, the transmission error status information represented by two or more bits may include transmission error status (a pass or a fail) of each data line or the number of transmission error bits on each data line. For example, in the transmission error status information represented by five bits, three bits may represent an index of a data line having a transmission error, and two bits may represent the number of transmission error bits in the data line.

The NVM may include an error detection circuit 121 and a retraining decision circuit 122. The error detection circuit 121 may perform transmission error detection on each of the data lines DQ, based on transmission parity data. The error detection circuit 121 may determine whether there is an error in sub data (or a codeword) received through each of the data lines DQ or may count the number of transmission error bits included in the sub data (or a codeword) received through each of the data lines DQ (i.e., the number of transmission error bits per codeword on each data line). In other words, the error detection circuit 121 may generate an error detection result, which includes existence or non-existence of a transmission error on each data line or the number of transmission error bits on each data line.

The retraining decision circuit 122 may determine whether a retraining condition is satisfied, based on the error detection result. For example, the retraining decision circuit 122 may determine whether to retrain all the data lines DQ or at least one of the data lines DQ by determining whether the existence or non-existence of a transmission error on each of the data lines DQ or the number of transmission error bits on each of the data lines DQ meets a threshold condition.

Accordingly, the storage device 100 may not perform a monitoring operation in which a temperature or voltage change of each NVM is periodically monitored. The NVM may detect an error based on transmission parity data. The NVM may provide transmission error status information to the storage controller 110. The storage device 100 may carry out retraining without performance degradation.

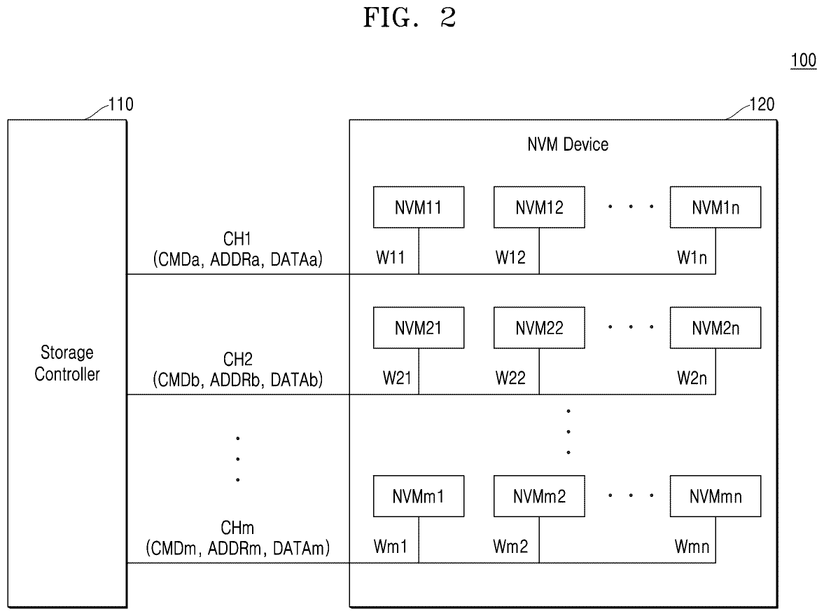

FIG. 2 is a detailed block diagram of the storage device 100 of FIG. 1.

Referring to FIGS. 1 and 2, the storage device 100 may include the NVM device 120 and the storage controller 110. The storage device 100 may support a plurality of channels CH1 to CHm, and the NVM device 120 and the storage controller 110 may be connected to each other through the channels CH1 to CHm. For example, the storage device 100 may correspond to a storage device such as an SSD.

The NVM device 120 may include a plurality of non-volatile memories NVM 11 to NVM mn. Each of the non-volatile memories NVM 11 to NVM mn may correspond to an NVM in FIG. 1. Each of the non-volatile memories NVM 11 to NVM mn may be connected to one of the channels CH1 to CHm through a way corresponding to each of the non-volatile memories NVM 11 to NVM mn. For example, the non-volatile memories NVM 11 to NVM In may be connected to the first channel CH1 through ways W11 to W1n, respectively, and the non-volatile memories NVM 21 to NVM 2n may be connected to the second channel CH2 through ways W21 to W2n, respectively. In an implementation, each of the non-volatile memories NVM 11 to NVM mn may be implemented in a certain memory unit, which may operate according to an individual command from the storage controller 110. For example, each of the non-volatile memories NVM 11 to NVM mn may be implemented in a chip or a die. However, implementations are not limited thereto.

The storage controller 110 may exchange signals with the NVM device 120 through the channels CH1 to CHm. For example, the storage controller 110 may transmit commands CMDa to CMDm, addresses ADDRa to ADDRm, and data DATAa to DATAm to the NVM device 120 through the channels CH1 to CHm and receive the DATAa to DATAm from the NVM device 120 through the channels CH1 to CHm.

The storage controller 110 may select one non-volatile memory among the non-volatile memories NVM 11 to NVM mn, which are connected to their corresponding one of the channels CH1 to CHm, and exchange signals with the selected non-volatile memory through the corresponding channel. For example, the storage controller 110 may select the non-volatile memory NVM 11 among the non-volatile memories NVM 11 to NVM In connected to the channel CH1. The storage controller 110 may transmit the command CMDa, the address ADDRa, and the data DA TA a to the non-volatile memory NVM 11 or receive the data DA TA a from the non-volatile memory NVM 11 through the channel CH1.

The storage controller 110 may exchange signals in parallel with the NVM device 120 through different channels. For example, while the storage controller 110 is transmitting the command CMDa to the NVM device 120 through the channel CH1, the storage controller 110 may transmit the command CMDb to the NVM device 120 through the channel CH2. For example, while the storage controller 110 is receiving the data DATAa from the NVM device 120 through the channel CH1, the storage controller 110 may receive the data DATAb from the NVM device 120 through the channel CH2.

In an implementation, while the storage controller 110 is performing retraining on the non-volatile memory NVM 11 connected to the channel CH1, the storage controller 110 may perform a read operation or a write operation on the non-volatile memory NVM 21 connected to the channel CH2.

The storage controller 110 may generally control operations of the NVM device 120. The storage controller 110 may transmit signals to the channels CH1 to CHm and thus individually control the non-volatile memories NVM 11 to NVM mn connected to the channels CH1 to CHm. For example, the storage controller 110 may transmit the command CMDa and the address ADDRa to the channel CH1 and thus control one non-volatile memory selected from the non-volatile memories NVM 11 to NVM In.

Each of the non-volatile memories NVM 11 to NVM mn may operate under control by the storage controller 110. For example, the non-volatile memory NVM 11 may program the data DATAa according to the command CMDa, the address ADDRa, and the data DATAa, which are provided to the channel CH1. For example, the non-volatile memory NVM 21 may read the data DATAb according to the command CMDb and the address ADDRb, which are provided to the channel CH2, and transmit the data DATAb to the storage controller 110.

Although it is illustrated in FIG. 2 that the NVM device 120 communicates with the storage controller 110 through “m” channels and the NVM device 120 includes “n” non-volatile memories in correspondence to each channel, the number of channels and the number of non-volatile memories connected to each channel may be variously changed.

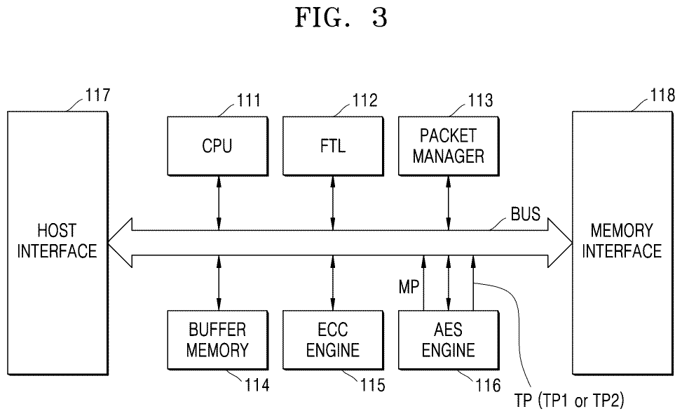

FIG. 3 is a detailed block diagram of the storage controller 110 in FIG. 1.

Referring to FIGS. 1 and 3, the storage controller 110 may include a central processing unit (CPU) 111, a host interface 117, and a memory interface 118. The storage controller 110 may further include a flash translation layer (FTL) 112, a packet manager 113, a buffer memory 114, an error correction code (ECC) engine 115, and an advanced encryption standard (AES) engine 116. The storage controller 110 may further include a working memory (not shown) to which the FTL 112 is loaded. When the CPU 111 executes the FTL 112, data write and read operations of an NVM device may be controlled.

In an implementation, the host interface 117 may include at least one of various interfaces, such as a double data rate (DDR) interface, a low-power DDR (LPDDR) interface, a universal serial bus (USB) interface, a multimedia card (MMC) interface, a peripheral component interconnection (PCI) interface, a PCI-express (PCI-E) interface, an advanced technology attachment (ATA) interface, a serial ATA (SATA) interface, a parallel ATA (PATA) interface, a small computer system interface (SCSI), an enhanced small disk interface (ESDI), an integrated drive electronics (IDE) interface, a mobile industry processor interface (MIPI), an NVM-express (NVMe) interface, and a universal flash storage (UFS) interface.

The host interface 117 may exchange packets with a host (not shown). A packet transmitted from the host to the host interface 117 may include a command or data to be written to the NVM device 120. A packet transmitted from the host interface 117 to the host may include a response to a command or data read from the NVM device 120. The memory interface 118 may transmit, to the NVM device 120, data to be written to the NVM device 120 or may receive data read from the NVM device 120. The memory interface 118 may be implemented to comply with a standard, such as Toggle or ONFI.

The FTL 112 may perform various functions, such as address mapping, wear-leveling, and garbage collection. Address mapping is an operation of changing a logical address received from a host into a physical address actually used to store data in the NVM device 120. Wear-leveling is technology for preventing excessive degradation of a block by allowing blocks of the NVM device 120 to be uniformly used. For example, the wear-leveling may be implemented as a firmware technique for balancing the erase counts of physical blocks. Garbage collection is technology for securing the available capacity of the NVM device 120 by copying valid data of an old block to a new block and erasing the old block.

The packet manager 113 may generate a packet according to an interface protocol agreed between the host and the packet manager 113 or may parse various kinds of information from a packet received from the host. The buffer memory 114 may temporarily store data to be written to the NVM device 120 or data read from the NVM device 120. The buffer memory 114 may be included in the storage controller 110 or may be provided outside the storage controller 110.

The ECC engine 115 may detect and correct an error in data read from the NVM device 120. In detail, the ECC engine 115 may generate parity bits with respect to data to be written to the NVM device 120, and the parity bits may be stored in the NVM device 120 together with the data. When data is read from the NVM device 120, the ECC engine 115 may correct an error in the data using parity bits, which are read from the NVM device 120 together with the read data, and may output error-corrected read data.

In an implementation, the ECC engine 115 may generate memory parity data MP. The ECC engine 115 may generate the memory parity data M P to detect an error in data read from an NVM. The ECC engine 115 may use the memory parity data MP to supplement memory cell reliability.

In an implementation, the ECC engine 115 may generate transmission parity data TP. The ECC engine 115 may divide data into pieces by as many as the number of data lines. The ECC engine 115 may divide data into pieces of sub data. The ECC engine 115 may generate the transmission parity data TP for each piece of sub data. The transmission parity data TP may be used to compensate for a channel error or a transmission error.

The transmission parity data TP may correspond to the first transmission parity data TP1 or the second transmission parity data TP2. The first transmission parity data TP1 may refer to parity data, which is transmitted from the storage controller 110 to an NVM through a data line and used by the NVM to count the number of error bits resulting from a transmission error in the data line. The second transmission parity data TP2 may refer to parity data, which is transmitted from the storage controller 110 to an NVM through a data line and used by the NVM to determine whether there is a transmission error in the data line. For example, the second transmission parity data TP2 may include a CRC value of transmitted data.

In an implementation, the ECC engine 115 may include an encoder. A method by which the encoder generates the first transmission parity data TP1 will be described with reference to FIGS. 8 to 14.

The AES engine 116 may perform at least one selected from encryption and decryption of data input to the storage controller 110 by using a symmetric-key algorithm.

As the input/output speed between the storage controller 110 and an NVM increases, the range of a valid window may decrease. In addition, a channel error rate may increase during data transmission. During initialization, training may be performed to secure a maximum margin in a valid window. However, during an input/output operation, temperature and voltage changes of an NVM may increase. Accordingly, skew may occur between a signal of the data strobe line DQS and a signal of each of the data lines DQ. Due to the skew, the NVM may store data including an error. Although the reliability of memory cells is satisfactory (that is, memory cells maintain normal distribution), data including an error may be stored in a pattern, in which an uncorrectable ECC (UECC) occurs during a read operation, due to a channel transmission error. Accordingly, retraining is required.

In a comparative example, the storage controller 110 may monitor temperature and voltage changes of an NVM to determine whether to perform retraining. The storage controller 110 may request an oscillator value of a data strobe signal from the NVM. The storage controller 110 may request delay information of a data strobe signal from the NVM. The storage controller 110 may request a phase change in a signal of the data strobe line DQS or each of the data lines DQ from the NVM. To increase the accuracy of an oscillator request command, significant time may be required. The storage controller 110 may perform a monitoring operation (or a polling operation) on even an NVM that does not need retraining, by periodically transmitting an oscillator request command to the NVM. Accordingly, the performance of the storage device 100 may degrade. In other words, as the storage controller 110 periodically transmits an oscillator request command, the input/output performance of the storage controller 110 may decrease. In other words, the sequential performance and quality of service (QoS) latency of the storage device 100 may decrease.

According to the present disclosure, the storage controller 110 may determine a retraining timing. The storage controller 110 may determine whether retraining is required for each NVM. The storage controller 110 may determine whether retraining is required, based on transmission error status information. The storage controller 110 may perform retraining of an NVM, in response to the transmission error status information. The storage controller 110 may determine whether a program fail is caused by a memory cell error or a channel transmission error, based on the transmission error status information. Accordingly, without performance degradation, a channel error between the storage controller 110 and an NVM may be detected in real time.

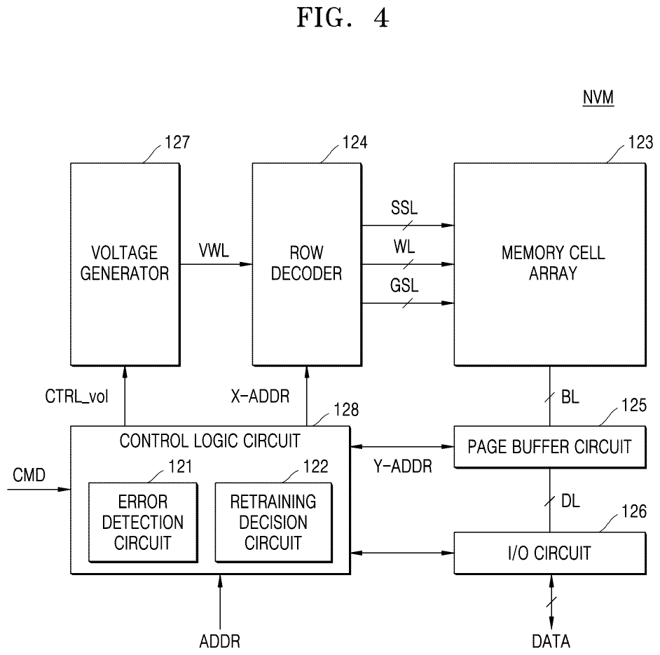

FIG. 4 is a detailed block diagram of an NVM in FIG. 1.

The NVM of FIG. 4 may correspond to any one of the non-volatile memories NVM 11 to NVM mn in FIG. 2. Referring to FIGS. 1 and 4, the NVM may include a memory cell array 123, a row decoder 124, a page buffer circuit 125, an input/output (I/O) circuit 126, a voltage generator 127, and a control logic circuit 128. Although not shown in FIG. 4, the NVM may further include a column logic, a pre-decoder, a temperature sensor, a command decoder, an address decoder, and/or the like. In an implementation, the NVM may correspond to an NVM device such as a NAND flash memory device, but the scope of the present disclosure is not limited thereto.

For example, the memory cell array 123 may correspond to a core of the NVM. The row decoder 124, the page buffer circuit 125, the I/O circuit 126, and the control logic circuit 128 may correspond to peripheral circuits of the NVM. The peripheral circuits may be configured to access the core.

The memory cell array 123 may include a plurality of memory blocks. Each of the memory blocks may include a plurality of memory cells. The memory cell array 123 may be connected to the page buffer circuit 125 through bit lines BL and connected to the row decoder 124 through word lines WL, string select lines SSL, and ground select lines GSL.

In an implementation, the memory cell array 123 may include a three-dimensional (3D) memory cell array, which may include a plurality of strings. Each of the strings may include memory cells respectively connected to word lines, which are vertically stacked on a substrate. The disclosures of U.S. Pat. Nos. 7,679,133, 8,553,466, 8,654,587, 8,559,235, and U.S. Patent Application No. 2011/0233648 are incorporated herein in their entirety by reference.

The row decoder 124 may receive a row address X-ADDR from the control logic circuit 128. The row decoder 124 may decode the row address X-ADDR and may control or drive a voltage of each of the string select lines SSL, the word lines WL, and the ground select lines GSL, based on a result of the decoding. For example, based on the decoding result, the row decoder 124 may provide a corresponding operating voltage to each of the string select lines SSL, the word lines WL, and the ground select lines GSL.

In response to the row address X-ADDR, the row decoder 124 may select one of the word lines WL and one of the string select lines SSL. For example, the row decoder 124 may apply a program voltage and a program verify voltage to a selected word line in a program operation and apply a read voltage to the selected word line in a read operation.

The page buffer circuit 125 may be connected to the memory cell array 123 through the bit lines BL. The page buffer circuit 125 may select at least one of the bit lines BL, in response to a column address Y-ADDR. The page buffer circuit 125 may operate as a write driver or a sense amplifier according to an operation mode. For example, the page buffer circuit 125 may receive data from the I/O circuit 126 and temporarily store the received data. The page buffer circuit 125 may control a voltage of the bit lines BL such that the data temporarily stored in the page buffer circuit 125 may be stored in the memory cell array 123. The page buffer circuit 125 may read data from the memory cell array 123 by sensing a voltage change in the bit lines BL. The page buffer circuit 125 may transmit the read data to the I/O circuit 126.

The I/O circuit 126 may exchange data with an external device (e.g., a storage controller). In an implementation, the I/O circuit 126 may output data to an external device or receive data from the external device in synchronization with a data strobe signal.

The voltage generator 127 may generate various kinds of voltages for performing program, read, and erase operations, based on a voltage control signal CTRL_vol. For example, the voltage generator 127 may generate, as a word line voltage VWL, a program voltage, a read voltage, a program verify voltage, or an erase voltage.

The control logic circuit 128 may generally control various operations of the NVM. The control logic circuit 128 may output various control signals, in response to a command CMD and/or an address ADD, each received from the storage controller 110. For example, the control logic circuit 128 may output the voltage control signal CTRL_vol, the row address X-ADDR, and the column address Y-ADDR.

The control logic circuit 128 may include the error detection circuit 121 and the retraining decision circuit 122. The error detection circuit 121 may perform transmission error detection. The error detection circuit 121 may perform decoding based on received transmission parity data. The error detection circuit 121 may detect an error in sub data (or a codeword) by using the transmission parity data. The error detection circuit 121 may generate an error detection result by detecting existence or non-existence of an error or the number of errors with respect to sub data (or a codeword) corresponding to each of a plurality of data lines.

The transmission parity data may correspond to first transmission parity data or second transmission parity data. Here, the first transmission parity data may refer to parity data, which is transmitted from the storage controller 110 to the NVM through each of the data lines and used by the NVM to count the number of error bits resulting from transmission errors on a given data line. The second transmission parity data may refer to parity data, which is transmitted from the storage controller 110 to the NVM through each of the data lines and used by the NVM to determine whether there is a transmission error on a given data line. For example, the second transmission parity data may correspond to a CRC value of transmitted data.

Here, according to the purpose and scope of error detection, the first transmission parity data and the second transmission parity data may be transmitted through the same data line, or the first transmission parity data or the second transmission parity data may be transmitted through multiple data lines so that the first transmission parity data or the second transmission parity data is transmitted through each data line without overlap. Alternatively, the first transmission parity data or the second transmission parity data may be transmitted through each of the data lines.

The retraining decision circuit 122 may determine whether a retraining of the NVM is required, based on the error detection result. When existence or non-existence of a transmission error on each of the data lines or the number of transmission error bits on each of the data lines meets a threshold condition according to the error detection result, the retraining decision circuit 122 may determine that a retraining condition is satisfied. Here, retraining conditions (i.e., threshold conditions) may be variously combined.

In an implementation, the transmission parity data may correspond to the first transmission parity data. The error detection circuit 121 may count the number of transmission error bits with respect to each of the data lines, based on the first transmission parity data. The retraining decision circuit 122 may determine whether a condition for performing retraining is satisfied, based on a counting result generated from the counting operation.

In some implementations, the transmission parity data may correspond to the second transmission parity data. The error detection circuit 121 may determine whether there is a transmission error on each of the data lines, based on the second transmission parity data. The retraining decision circuit 122 may determine whether a condition for performing retraining is satisfied, based on a determination result generated from the determination operation.

In some implementations, transmission parity data may include the first transmission parity data and the second transmission parity data. In other words, a first group of pieces of transmission parity data may correspond to the first transmission parity data, and a second group of pieces of transmission parity data may correspond to the second transmission parity data. Here, a first group of data lines may transmit the first transmission parity data corresponding to the first group from the storage controller 110 to the NVM, and a second group of data lines may transmit the second transmission parity data corresponding to the second group from the storage controller 110 to the NVM. The error detection circuit 121 may count the number of transmission error bits on each of the data lines in the first group, based on the first transmission parity data. The error detection circuit 121 may determine whether there is a transmission error on each of the data lines in the second group, based on the second transmission parity data. The retraining decision circuit 122 may determine whether a condition for performing retraining is satisfied, based on a counting result generated from the counting operation and a determination result generated from the determination operation.

When the retraining decision circuit 122 determines that retraining is not required, based on a result of the transmission error detection, the NVM may perform a write operation of received data.

When the retraining decision circuit 122 determines that retraining is required, based on the result of the transmission error detection, the NVM may provide transmission error status information to the storage controller 110. Here, the transmission error status information may refer to information about an error that has occurred during data transmission through a data line and may include whether to perform retraining on all the data lines, whether to perform retraining on each of the data lines, or the number of transmission error bits on each data line. In this case, the NVM may not perform a write operation on the received data.

The NVM may provide transmission error status information to the storage controller 110, in response to a status read command of the storage controller 110. Here, the status read command may be referred to as a get-feature command.

In an implementation, the NVM may provide the storage controller 110 with the transmission error status information corresponding to whether retraining of all the data lines is required. In other words, the NVM may determine whether retraining of all the data lines is required. For example, the transmission error status information may be represented by one bit and may indicate a transmission error status (a pass or a fail) of all the data lines. For example, when the transmission error status of all the data lines is a pass, the NVM may transmit the transmission error status information corresponding to “1” to the storage controller 110. When the transmission error status of all the data lines is a fail, the NVM may transmit the transmission error status information corresponding to “0” to the storage controller 110.

In some implementations, the NVM may provide the storage controller 110 with the transmission error status information, which corresponds to whether retraining of each of the data lines is required or the number of transmission error bits on each of the data lines. In other words, the retraining decision circuit 122 may determine whether retraining is required for each data line, or the error detection circuit 121 may count the number of transmission error bits on each of the data lines. For example, the NVM may provide the storage controller 110 with transmission error status information represented by two or more bits. Here, the transmission error status information represented by two or more bits may include transmission error status (a pass or a fail) of each data line or the number of transmission error bits on each data line. For example, in the transmission error status information represented by five bits, three bits may represent an index of a data line having a transmission error, and two bits may represent the number of transmission error bits in the data line.

As described above, the NVM may detect an error in each write operation, based on the transmission parity data, which corresponds to the first transmission parity data or the second transmission parity data. The NVM may provide transmission error status information to the storage controller 110 when retraining is required or in response to a status read command of the storage controller 110. Accordingly, the NVM may not store data including a transmission error and may immediately recover the data.

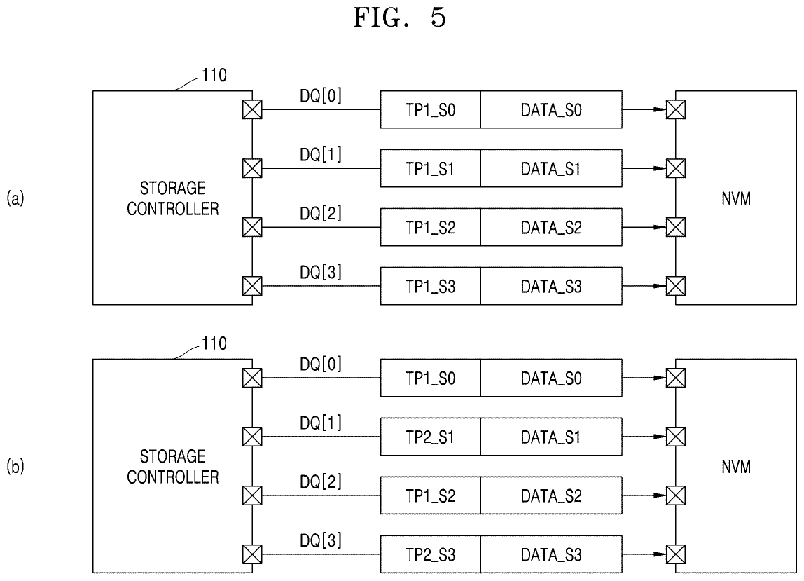

FIG. 5 is a detailed block diagram illustrating the storage controller 110 and the NVM in FIG. 1, according to an implementation.

Referring to (a) and (b) of FIG. 5, four data lines DQ[0], DQ[1], DQ[2], and DQ[3] connecting the storage controller 110 to the NVM are illustrated as an example. However, the scope of the present disclosure is not limited thereto. The number of data lines may decrease or increase according to an implementation.

It may be seen that (a) of FIG. 5 illustrates a case where the transmission parity data includes only the pieces of first transmission parity data TP1_S0, TP1_S1, TP1_S2, and TP1_S3. It may be seen that (b) of FIG. 5 illustrates a case where the transmission parity data includes two pieces of first transmission parity data TP1_S0 and TP1_S2 and two pieces of second transmission parity data TP2_S1 and TP2_S3. The case shown in (b) of FIG. 5 is just an example, and the number of data lines transmitting the first transmission parity data and the number of data lines transmitting the second transmission parity data may vary with an implementation.

Here, the first transmission parity data may refer to parity data, which is used by the NVM to count the number of error bits resulting from transmission errors on a given data line. The second transmission parity data may refer to parity data, which is used by the NVM to determine whether there is a transmission error on a given data line. For example, the second transmission parity data may correspond to a CRC value of transmitted data.

The storage controller 110 may divide data to be transmitted into pieces by as many as the number of data lines. Referring to (a) and (b) of FIG. 5, the storage controller 110 may generate four pieces of sub data DATA_S0, DATA_S1, DATA_S2, and DATA_S3 by dividing data to be transmitted into pieces as many as four data lines. Hereinafter, one piece of sub data and one piece of transmission parity data may be referred to as one codeword according to the context.

The storage controller 110 may generate transmission parity data with respect to sub data. The transmission parity data may correspond to the first transmission parity data or the second transmission parity data. Referring to (a) of FIG. 5, the storage controller 110 may generate the first transmission parity data corresponding to each of the four pieces of sub data DATA_S0, DATA_S1, DATA_S2, and DATA_S3. Referring to (b) of FIG. 5, the storage controller 110 may generate two pieces of first transmission parity data TP1_S0 and TP1_S2 respectively corresponding to two pieces of sub data DATA_S0 and DATA_S2 and two pieces of second transmission parity data TP2_S1 and TP2_S3 respectively corresponding to two pieces of sub data DATA_S1 and DATA_S3.

Referring to (a) of FIG. 5, the storage controller 110 may transmit sub data and the first transmission parity data corresponding to the sub data to each data line. For example, the storage controller 110 may transmit the four pieces of sub data DATA_S0, DATA_S1, DATA_S2, and DATA_S3 and the four pieces of first transmission parity data TP1_S0, TP1_S1, TP1_S2, and TP1_S3, respectively corresponding to the four pieces of sub data DATA_S0, DATA_S1, DATA_S2, and DATA_S3 to the NVM through the four data lines DQ[0], DQ[1], DQ[2], and DQ[3].

Referring to (b) of FIG. 5, the storage controller 110 may transmit sub data and the first transmission parity data corresponding to the sub data through a first group of data lines and may transmit sub data and the second transmission parity data corresponding to the sub data through a second group of data lines. For example, the storage controller 110 may transmit the two pieces of sub data DATA_S0 and DATA_S2 and the two pieces of first transmission parity data TP1_S0 and TP1_S2 respectively corresponding to the two pieces of sub data DATA_S0 and DATA_S2 to the NVM through the first group of two data lines DQ[0] and DQ[2]. The storage controller 110 may transmit the two pieces of sub data DATA_S1 and DATA_S3 and the two pieces of second transmission parity data TP2_S1 and TP2_S3 respectively corresponding to the two pieces of sub data DATA_S1 and DATA_S3 to the NVM through the second group of two data lines DQ[1] and DQ[3].

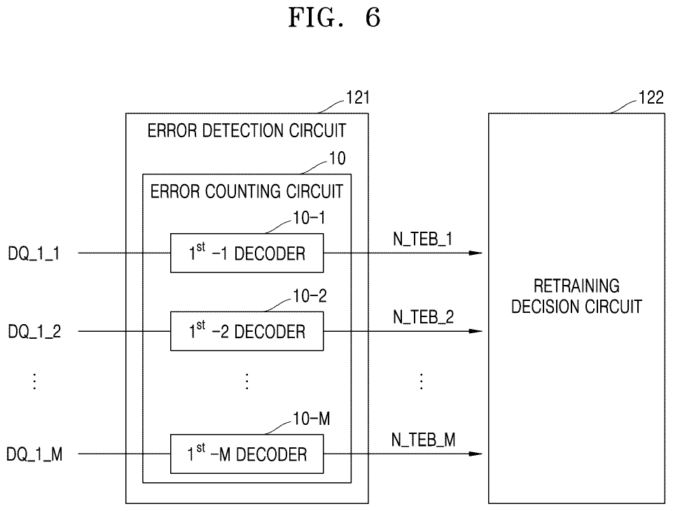

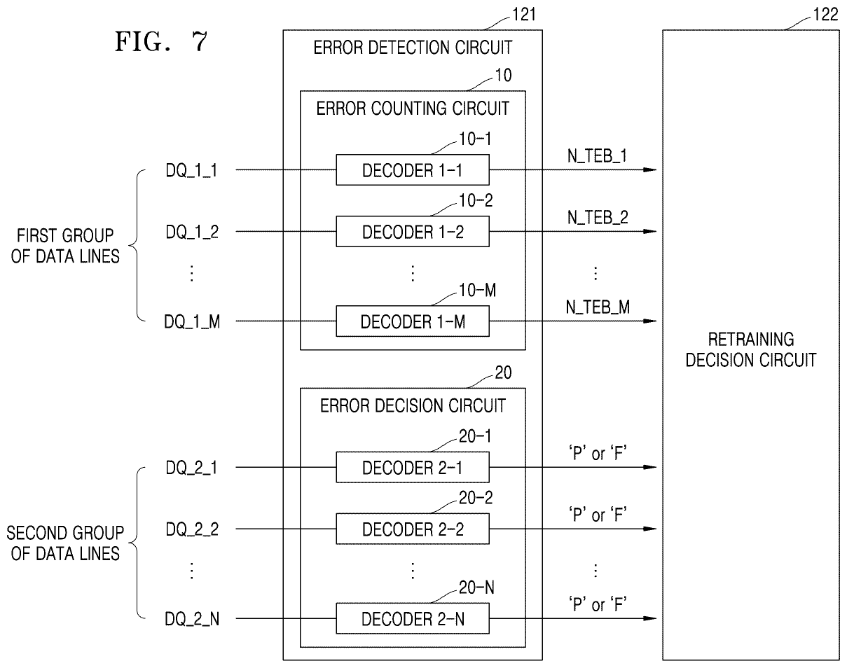

Hereinafter, the implementation according to (a) of FIG. 5 is generalized in terms of the number of data lines to describe the error detection circuit 121 and the retraining decision circuit 122 in FIG. 4 with reference to FIG. 6. The implementation according to (b) of FIG. 5 is generalized in terms of the number of data lines to describe the error detection circuit 121 and the retraining decision circuit 122 in FIG. 4 with reference to FIG. 7.

FIG. 6 is a detailed block diagram illustrating the error detection circuit 121 and the retraining decision circuit 122 in FIG. 4, according to an implementation.

Referring to FIG. 6, the NVM may include the error detection circuit 121 and the retraining decision circuit 122.

According to the implementation of FIG. 6, the error detection circuit 121 may include an error counting circuit 10.

The error counting circuit 10 may include 1^{st}-1 to 1^{st}-M decoders 10-1 to 10-M. Here, M may be a positive integer. For example, in the implementation according to (a) of FIG. 5, M may be 4.

Each of the 1^{st}-1 to 1^{st}-M decoders 10-1 to 10-M may receive data transmitted through a data line correspond thereto. For example, the 1^{st}-1 decoder 10-1 may receive data transmitted through a first data line DQ_1_1. The 1^{st}-2 decoder 10-2 may receive data transmitted through a second data line DQ_1_2. The 1^{st}-M decoder 10-M may receive data transmitted through an M-th data line DQ_1_M.

Each of the 1^{st}-1 to 1^{st}-M decoders 10-1 to 10-M may perform transmission error detection. For example, each of the 1^{st}-1 to 1^{st}-M decoders 10-1 to 10-M may count transmission error bits in the received data. Each of the 1^{st}-1 to 1^{st}-M decoders 10-1 to 10-M may count transmission error bits based on the first transmission parity data.

For example, the 1^{st}-1 decoder 10-1 may count transmission error bits in data received through the first data line DQ_1_1. The 1^{st}-2 decoder 10-2 may count transmission error bits in data received through the second data line DQ_1_2. The 1^{st}-M decoder 10-M may count transmission error bits in data received through the M-th data line DQ_1_M.

The error detection circuit 121 may generate an error detection result. The error detection result may include first to M-th counting results N_TEB_1 to N_TEB_M. The 1^{st}-1 decoder 10-1 may generate the first counting result N_TEB_1, the 1^{st}-2 decoder 10-2 may generate the second counting result N_TEB_2, and the 1^{st}-M decoder 10-M may generate the M-th counting result N_TEB_M. The error detection circuit 121 may provide the error detection result to the retraining decision circuit 122.

The retraining decision circuit 122 may receive the error detection result. The retraining decision circuit 122 may receive a threshold condition. The storage controller 110 may set the threshold condition through a threshold condition setting command. Here, the threshold condition setting command may be referred to as a set-feature command. The retraining decision circuit 122 may store the threshold condition. In some implementations, the threshold condition may be predetermined or may be prestored in the retraining decision circuit 122.

The retraining decision circuit 122 may determine whether a retraining condition is satisfied, based on the error detection result and the threshold condition. The retraining decision circuit 122 may generate a determination result. The control logic circuit 128 may generate transmission error status information, based on the determination result of the retraining decision circuit 122 and/or the error detection result of the error detection circuit 121.

FIG. 7 is a detailed block diagram illustrating the error detection circuit 121 and the retraining decision circuit 122 in FIG. 4, according to an implementation.

Referring to FIG. 7, the NVM may include the error detection circuit 121 and the retraining decision circuit 122.

According to the implementation of FIG. 7, the error detection circuit 121 may include the error counting circuit 10 and an error decision circuit 20. Compared to the error detection circuit 121 in FIG. 6, the error detection circuit 121 in FIG. 7 may further include the error decision circuit 20.

The error counting circuit 10 may include the 1^{st}-1 to 1^{st}-M decoders 10-1 to 10-M. The error decision circuit 20 may include 2^{nd}-1 to 2^{nd}-N decoders 20-1 to 20-N. Here, M and N may be positive integers, and M+N may be the total number of data lines. For example, in the implementation according to (b) of FIG. 5, M may be 2 and N may be 2.

The data lines may be classified into two groups according to transmission parity data which each of the data lines transmits. Data lines transmitting the first transmission parity data may be classified as a first group, and data lines transmitting the second transmission parity data may be classified as a second group. For example, in (b) of FIG. 5, the two data lines DQ[0] and DQ[2] may correspond to data lines in the first group, and the two data lines DQ[1] and DQ[3] may correspond to data lines in the second group.

Each of the 1^{st}-1 to 1^{st}-M decoders 10-1 to 10-M may receive data transmitted through a corresponding data line in the first group. For example, the 1^{st}-1 decoder 10-1 may receive data transmitted through the first data line DQ_1_1 in the first group. The 1^{st}-2 decoder 10-2 may receive data transmitted through the second data line DQ_1_2 in the first group. The 1^{st}-M decoder 10-M may receive data transmitted through the M-th data line DQ_1_M in the first group.

Each of the 2^{nd}-1 to 2^{nd}-N decoders 20-1 to 20-N may receive data transmitted through a corresponding data line in the second group. For example, the 2^{nd}-1 decoder 20-1 may receive data transmitted through a first data line DQ_2_1 in the second group. The 2^{nd}-2 decoder 20-2 may receive data transmitted through a second data line DQ_2_2 in the second group. The 2^{nd}-N decoder 20-N may receive data transmitted through an N-th data line DQ_2_N in the second group.

Each of the 1^{st}-1 to 1^{st}-M decoders 10-1 to 10-M may perform transmission error detection. For example, each of the 1^{st}-1 to 1^{st}-M decoders 10-1 to 10-M may count transmission error bits in received data. Each of the 1^{st}-1 to 1^{st}-M decoders 10-1 to 10-M may count transmission error bits based on a corresponding piece of the first transmission parity data.

For example, the 1^{st}-1 decoder 10-1 may count transmission error bits in data received through the first data line DQ_1_1 in the first group. The 1^{st}-2 decoder 10-2 may count transmission error bits in data received through the second data line DQ_1_2 in the first group. The 1^{st}-M decoder 10-M may count transmission error bits in data received through the M-th data line DQ_1_M in the first group.

Each of the 2^{nd}-1 to 2^{nd}-N decoders 20-1 to 20-N may perform transmission error detection. For example, each of the 2^{nd}-1 to 2^{nd}-N decoders 20-1 to 20-N may determine whether there is a transmission error in received data. Each of the 2^{nd}-1 to 2^{nd}-N decoders 20-1 to 20-N may determine existence of non-existence of a transmission error, based on a corresponding piece of the second transmission parity data.

For example, the 2^{nd}-1 decoder 20-1 may determine whether there is a transmission error in data received through the first data line DQ_2_1 in the second group. The 2^{nd}-2 decoder 20-2 may determine whether there is a transmission error in data received through the second data line DQ_2_2 in the second group. The 2^{nd}-N decoder 20-N may determine whether there is a transmission error in data received through the N-the data line DQ_2_N in the second group.

The error detection circuit 121 may generate an error detection result. The error detection result may include the first to M-th counting results N_TEB_1 to N_TEB_M and first to N-th determination results. The 1^{st}-1 decoder 10-1 may generate the first counting result N_TEB_1, the 1^{st}-2 decoder 10-2 may generate the second counting result N_TEB_2, and the 1^{st}-M decoder 10-M may generate the M-th counting result N_TEB_M. The 2^{nd}-1 decoder 20-1 may generate a first determination result, P or F, the 2^{nd}-2 decoder 20-2 may generate a second determination result, P or F, and the 2^{nd}-N decoder 20-N may generate an N-th determination result, P or F. The error detection circuit 121 may provide the error detection result to the retraining decision circuit 122.

The retraining decision circuit 122 may receive the error detection result. The retraining decision circuit 122 may receive a threshold condition. The storage controller 110 may set the threshold condition through a threshold condition setting command. Here, the threshold condition setting command may be referred to as a set-feature command. The retraining decision circuit 122 may store the threshold condition. In some implementations, the threshold condition may be predetermined or may be prestored in the retraining decision circuit 122.

The retraining decision circuit 122 may determine whether a retraining condition is satisfied, based on the error detection result and the threshold condition. The retraining decision circuit 122 may generate a determination result. The control logic circuit 128 may generate transmission error status information, based on the determination result of the retraining decision circuit 122 and/or the error detection result of the error detection circuit 121.

According to an implementation, the second transmission parity data may correspond to a CRC value of transmitted data, which is used to estimate whether there is an error in the transmitted data.

The first transmission parity data or a codeword including the first transmission parity data may correspond to a code designed to estimate existence or non-existence of an error in transmitted data and the number of errors in the transmitted data. The first transmission parity data or a codeword including the first transmission parity data will be described with reference to FIG. 8 below.

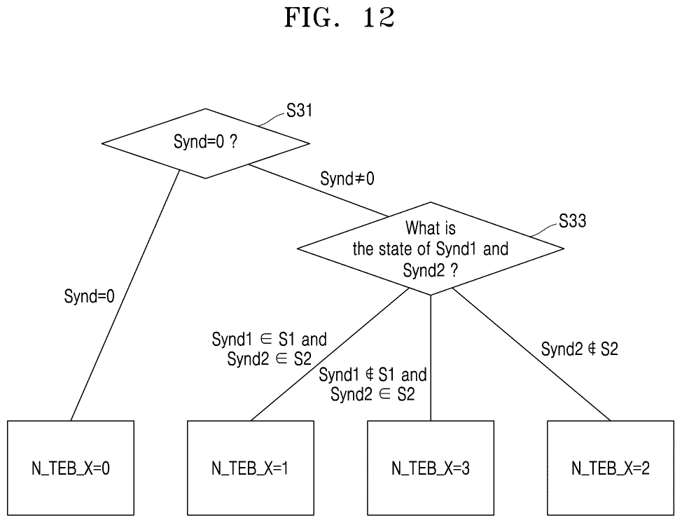

FIG. 8 is a block diagram illustrating an encoder included in a memory controller and a 1^{st}-X decoder included in an error counting circuit, according to an implementation. FIGS. 9 to 11 are diagrams illustrating shortened Hamming code encoding. FIGS. 12 to 14 are diagrams illustrating shortened Bose-Chaudhuri-Hocquenghem (BCH) code encoding.

Referring to FIG. 8, a storage device (e.g., the storage device 100 of FIG. 1) may include an encoder and a 1^{st}_X decoder 10-X. The encoder 30 may be included in the storage controller 110 in FIG. 1. According to an implementation, the encoder 30 may be included in the ECC engine 115 in FIG. 3. The 1^{st}-X decoder 10-X may correspond to one of the 1^{st}-1 to 1^{st}-M decoders 10-1 to 10-M described with reference to FIGS. 6 and 7. Here, X may be a positive integer that is at least 1 but not more than M.

When sub data DATA_S is received from the storage controller 110, the sub data DATA_S may be encoded by the encoder 30. In other words, the encoder 30 may generate encoded data by encoding the sub data DATA_S.

The encoder 30 may perform single-parity-checker (SPC)-based encoding, shortened Hamming code encoding, or shortened BCH code encoding on the sub data DATA_S.

The encoder 30 may provide encoded data, i.e., transmission data TD, to a data line DQ_X. The 1^{st}-X decoder 10-X may receive reception data RD from the data line DQ_X and decode the reception data RD, thereby generating a counting result N_TEB_X corresponding to the number of transmission error bits on the data line DQ_X. The reception data RD may include error E caused by various reasons (e.g., skew between a signal of a data line DQ and a signal of the data strobe line DQS).

The transmission data TD or the reception data RD may correspond to a codeword including sub data and the first transmission parity data, which have been described with reference to FIGS. 1 to 7.

A method of generating, performed by the encoder 30, the transmission data TD by performing SPC-based encoding on the sub data DATA_S and a method of generating, performed by the 1^{st}-X decoder 10-X, the counting result N_TEB_X, which corresponds to the number of transmission error bits on the data line DQ_X, by decoding the reception data RD will be described below.

The transmission data TD may correspond to a codeword that has undergone SPC-based encoding by the encoder 30. The reception data RD may correspond to data (or a codeword) in which the error E is in the transmission data TD.

For example, the encoder 30 may generate a codeword that has undergone SPC-based encoding, based on Equation 1.

$${H}_{spc} = [ \begin{matrix}1 & 0 & 0 & 0 & 1 & 0 & 0 & 0 & … & 1 & 0 & 0 & 0 \\ 0 & 1 & 0 & 0 & 0 & 1 & 0 & 0 & … & 0 & 1 & 0 & 0 \\ 0 & 0 & 1 & 0 & 0 & 0 & 1 & 0 & … & 0 & 0 & 1 & 0 \\ 0 & 0 & 0 & 1 & 0 & 0 & 0 & 1 & … & 0 & 0 & 0 & 1\end{matrix} ] \qquad [ Equation 1 ]$$

$$SD = ( \begin{matrix}m 1 \\ m 2 \\ ⋮ \\ mN\end{matrix} ) , TD = ( \begin{matrix}m 1 \\ m 2 \\ ⋮ \\ mN \\ tP 1 \\ tP 2 \\ tP 3 \\ tP 4\end{matrix} )$$

$${S}_{SPC} = {H}_{spc} * TD = ( \begin{matrix}0 \\ 0 \\ 0 \\ 0\end{matrix} )$$

Here, H_{spc} may represent a parity-check matrix in which

$$( \begin{matrix}1 & 0 & 0 & 0 \\ 0 & 1 & 0 & 0 \\ 0 & 0 & 1 & 0 \\ 0 & 0 & 0 & 1\end{matrix} )$$

size 4×(N+4) is repeated in a row direction, SD may represent N elements of the sub data DATA_S as a column vector of size N×1, TD, as transmission data, may represent SD plus four transmission parity bits tP1, tP2, tP3, and tP4, which are added to the last row of the SD, and S_{spc} may represent a syndrome matrix.

The encoder 30 may perform encoding of the sub data DATA_S by adding the four transmission parity bits tP1, tP2, tP3, and tP4 such that all elements of the modulo-2 product (i.e., the syndrome matrix, S_{spc}) of the parity-check matrix, H spc, and the transmission data TD become 0.

The 1^{st}-X decoder 10-X may generate the counting result N_TEB_X, based on Equation 2.

$${H}_{spc} = [ \begin{matrix}1 & 0 & 0 & 0 & 1 & 0 & 0 & 0 & … & 1 & 0 & 0 & 0 \\ 0 & 1 & 0 & 0 & 0 & 1 & 0 & 0 & … & 0 & 1 & 0 & 0 \\ 0 & 0 & 1 & 0 & 0 & 0 & 1 & 0 & … & 0 & 0 & 1 & 0 \\ 0 & 0 & 0 & 1 & 0 & 0 & 0 & 1 & … & 0 & 0 & 0 & 1\end{matrix} ] \qquad [ Equation 2 ]$$

$$RD = ( \begin{matrix}r 1 \\ r 2 \\ ⋮ \\ rN \\ rP 1 \\ rP 2 \\ rP 3 \\ rP 4\end{matrix} )$$

$${S}_{SPC} = {H}_{spc} * RD = ( \begin{matrix}1 or 0 \\ 1 or 0 \\ 1 or 0 \\ 1 or 0\end{matrix} )$$

Here, RD may represent reception data in which the error E is in the transmission data TD, and S_{spc} may represent a syndrome matrix.

The 1^{st}-X decoder 10-X may count 1s in the modulo-2 product (i.e., the syndrome matrix, S_{spc}) of the parity-check matrix, H_{spc}, and the reception data RD to obtain the number of transmission error bits on the data line DQ_X. Accordingly, the 1^{st}-X decoder 10-X may generate the counting result N_TEB_X corresponding to the number of transmission error bits on the data line DQ_X. In this case, the 1^{st}-X decoder 10-X may count up to four transmission error bits in the reception data RD.

In some implementations, the parity-check matrix, H_{spc}, in which

$$( \begin{matrix}1 & 0 & 0 & 0 \\ 0 & 1 & 0 & 0 \\ 0 & 0 & 1 & 0 \\ 0 & 0 & 0 & 1 \\ 1 & 0 & 0 & 0 \\ 0 & 1 & 0 & 0 \\ 0 & 0 & 1 & 0 \\ 0 & 0 & 0 & 1\end{matrix} )$$

of size 8×(N+4) is repeated in the row direction, may be used.

A method of generating, performed by the encoder 30, the transmission data TD by performing shortened Hamming code encoding on the sub data DATA_S and a method of generating, performed by the 1^{st}-X decoder 10-X, the counting result N_TEB_X, which corresponds to the number of transmission error bits on the data line DQ_X, by decoding the reception data RD will be described below with reference to FIGS. 9 to 11.

A method of counting, performed by the 1^{st}-X decoder 10-X, up to two transmission error bits in the reception data RD corresponding to a codeword based on shortened Hamming code encoding is described with reference to FIG. 9.

The transmission data TD may correspond to a codeword that has undergone shortened Hamming code encoding by the encoder 30. The reception data RD may correspond to data (or a codeword) in which the error E is in the transmission data TD.

It may be assumed that an original Hamming code is a (15, 11) Hamming code and a shortened Hamming code is a (10, 6) Hamming code in which five data bits in the original Hamming code are not used. In other words, in the original Hamming code (i.e., the (15, 11) Hamming code), the total number of bits in a codeword, n, may be 15, the number of data bits, k, may be 11, and the number of parity bits, m, may be 4. In the shortened Hamming code (i.e., the (10, 6) Hamming code), the total number of bits in a codeword, n′, may be 10, the number of data bits, k′, may be 6, and the number of parity bits, m, may be 4. The shortened Hamming code and the original Hamming code may have the same number of parity bits, “m”. However, the present disclosure is not limited thereto. According to implementations, parameters may be variously changed.

The encoder 30 may generate a codeword that has undergone shortened Hamming code encoding.

For example, the encoder 30 may generate a codeword, based on Equation 3.

$${G}_{shortened} = ( \begin{matrix}1 & 0 & 0 & 0 & 0 & 0 & 1 & 1 & 1 & 1 \\ 0 & 1 & 0 & 0 & 0 & 0 & 1 & 1 & 1 & 0 \\ 0 & 0 & 1 & 0 & 0 & 0 & 1 & 1 & 0 & 1 \\ 0 & 0 & 0 & 1 & 0 & 0 & 1 & 0 & 1 & 1 \\ 0 & 0 & 0 & 0 & 1 & 0 & 0 & 1 & 1 & 1 \\ 0 & 0 & 0 & 0 & 0 & 1 & 0 & 1 & 0 & 1\end{matrix} ) \qquad [ Equation 3 ]$$

$$c = m * {G}_{shortened}$$

Here, G_{shortened} may represent a generator matrix of the shortened Hamming code of size 6×10, “c”, as a codeword of size 1×10, may correspond to the transmission data TD, and “m”, as a data vector of size 1×6, may correspond to the sub data DATA_S. For example, the data vector may be represented as m=(1,0,1,1,0,1).

The 1^{st}-X decoder 10-X may generate the counting result N_TEB_X, based on the received codeword. The received codeword may be provided by the data line DQ_X and may have undergone shortened Hamming code encoding.

For example, the 1^{st}-X decoder 10-X may generate the counting result N_TEB_X, based on Equation 4.

$${H}_{sHamm} = [ \begin{matrix}1 & α & {α}^{2} & {α}^{3} & {α}^{4} & {α}^{5} & {α}^{6} & {α}^{7} & {α}^{8} & {α}^{9}\end{matrix} ] = [ \begin{matrix}1 & 0 & 0 & 0 & 1 & 0 & 0 & 1 & 1 & 0 \\ 0 & 1 & 0 & 0 & 1 & 1 & 0 & 1 & 0 & 1 \\ 0 & 0 & 1 & 0 & 0 & 1 & 1 & 0 & 1 & 0 \\ 0 & 0 & 0 & 1 & 0 & 0 & 1 & 1 & 0 & 1\end{matrix} ] \qquad [ Equation 4 ]$$

$$RD = ( \begin{matrix}r 1 \\ r 2 \\ ⋮ \\ r 6 \\ rP 1 \\ rP 2 \\ rP 3 \\ rP 4\end{matrix} )$$

$$Synd = {H}_{sHamm} * RD$$

$$S = \{ 1 , α , {α}^{2} , {α}^{3} , {α}^{4} , {α}^{5} , {α}^{6} , {α}^{7} , {α}^{8} , {α}^{9} \}$$

Here, α may represent a primitive element in the Galois field of order 2m=4, α and the powers of α may be transformed into different binary vectors of length 4, H_{sHamm} may represent a parity-check matrix of the shortened Hamming code, RD may be reception data in which the error E is in the transmission data TD, Synd may represent a syndrome matrix, and S may represent a set having, as an element, each column vector of the parity-check matrix of the shortened Hamming code.

Referring to FIG. 9 and Equation 4, the 1^{st}-X decoder 10-X may calculate the syndrome matrix, Synd, by performing modulo-2 multiplication of the reception data RD and the parity-check matrix, H_{sHamm}, of the shortened Hamming code and identify whether the syndrome matrix, Synd, is a zero matrix in operation S11.

When the syndrome matrix, Synd, is a zero matrix in operation S11, the 1^{st}-X decoder 10-X may count, as 0, the number of transmission error bits on the data line DQ_X. Accordingly, the 1^{st}-X decoder 10-X may generate the counting result N_TEB_X indicating that the number of transmission error bits on the data line DQ_X is 0.

When the syndrome matrix, Synd, is not a zero matrix in operation S11, operation S13 may be performed.

Referring to FIG. 9 and Equation 4, the 1^{st}-X decoder 10-X may identify whether the syndrome matrix, Synd, is an element included in the set, S.

When the syndrome matrix, Synd, is not a zero matrix, the 1^{st}-X decoder 10-X may count the number of transmission error bits as 1 or 2, based on whether the syndrome matrix, Synd, is an element included in the set, S.

When the syndrome matrix, Synd, is an element included in the set, S, in operation S13, the 1^{st}-X decoder 10-X may count, as 1, the number of transmission errors on the data line DQ_X. Accordingly, the 1^{st}-X decoder 10-X may generate the counting result N_TEB_X indicating that the number of transmission error bits on the data line DQ_X is 1. When the number of transmission error bits in the reception data RD is 1, the syndrome matrix, Synd, may correspond to one of ten column vectors included in the parity-check matrix, H_{sHamm}, of the shortened Hamming code and may not be calculated as shortened column vectors (α¹⁰, α¹¹, α¹², α¹³, α¹⁴).

When the syndrome matrix, Synd, is not an element included in the set, S, in operation S13, the 1^{st}-X decoder 10-X may count, as 2, the number of transmission errors on the data line DQ_X. Accordingly, the 1^{st}-X decoder 10-X may generate the counting result N_TEB_X indicating that the number of transmission error bits on the data line DQ_X is 2. When the syndrome matrix, Synd, does not correspond to one of ten column vectors included in the parity-check matrix, H_{sHamm}, of the shortened Hamming code, it may be determined that there are at least two transmission error bits, and accordingly, the number of transmission error bits in the reception data RD may be counted as 2.

In an implementation, the 1^{st}-X decoder 10-X may store all elements of the set, S, in advance as a lookup table (LUT). The 1^{st}-X decoder 10-X may compare the syndrome matrix, Synd, with all elements of the set, S, stored in advance as an LUT and may generate the counting result N_TEB_X corresponding to the number of transmission error bits on the data line DQ_X.

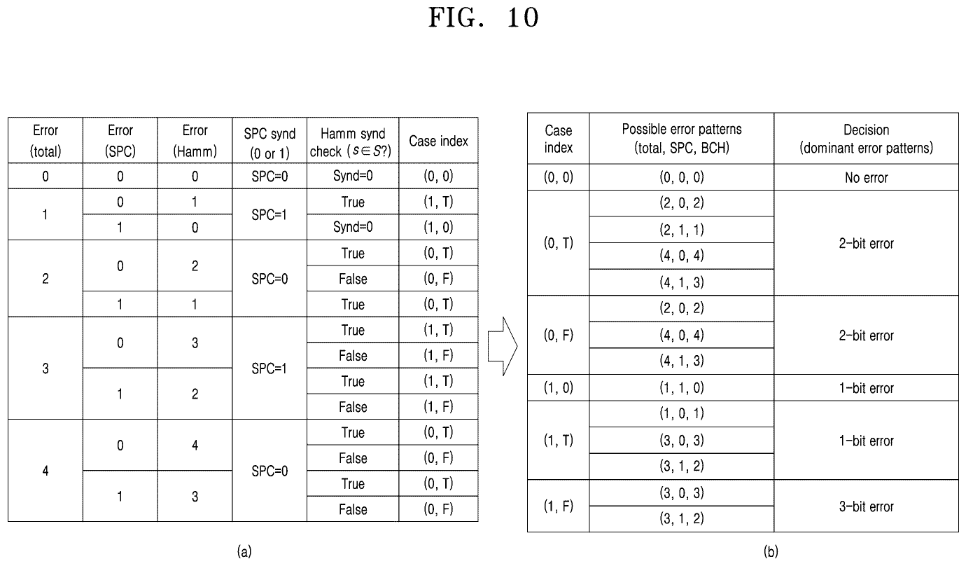

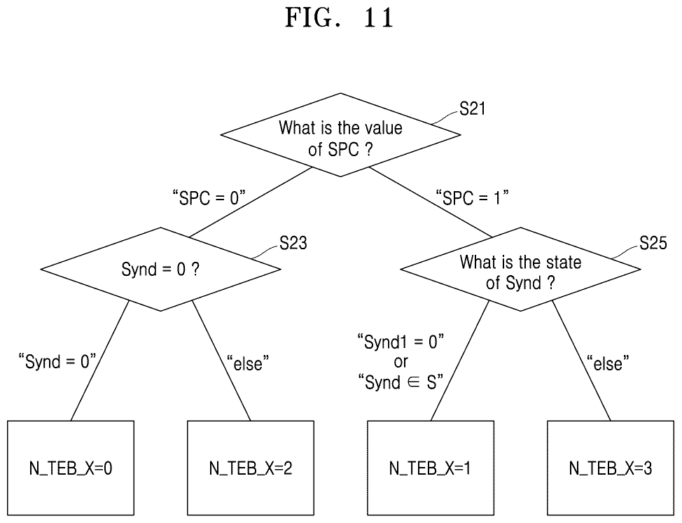

A method of counting, performed by the 1^{st}-X decoder 10-X, up to three transmission error bits in the reception data RD corresponding to a codeword based on shortened Hamming code encoding is described with reference to FIGS. 10 and 11.

The encoder 30 may generate a codeword that has undergone shortened Hamming code encoding.

For example, the encoder 30 may generate a codeword that has undergone shortened Hamming code encoding, based on Equation 3 described above and Equation 5 below.

$$TD = ( \begin{matrix}{c}^{T} \\ tSPC\end{matrix} ) = ( \begin{matrix}t 1 \\ t 2 \\ ⋮ \\ t 6 \\ tP 1 \\ tP 2 \\ tP 3 \\ tP 4 \\ tSPC\end{matrix} ) \qquad [ Equation 5 ]$$

Here, TD may represent transmission data, “c” may represent a codeword that has undergone shortened Hamming code encoding described in Equation 3, and t_{SPC} may represent an additional bit that makes the number of 1s in the transmission data TD an even number and may have a value of 1 or 0.

In other words, the encoder 30 may generate a final codeword by adding an additional bit to the codeword that has undergone shortened Hamming code encoding such that the number of 1s in the codeword becomes an even number.

For example, when the codeword, c, that has undergone shortened Hamming code encoding is (1, 0, 0, 1, 1, 1, 1, 1, 1), the number of 1s in the codeword, c, is an odd number. The encoder 30 may add the additional bit, t_{SPC}, having a value of 1 to the codeword, c, to make the number of 1s in the transmission data TD an even number, thereby generating the transmission data TD corresponding to the final codeword, (1, 0, 0, 1, 1, 1, 1, 1, 1, 1 (t_{SPC})). For example, when the codeword, c, that has undergone shortened Hamming code encoding is (1, 0, 0, 1, 1, 1, 1, 1, 0), the number of 1s in the codeword, c, is an even number. The encoder 30 may add the additional bit, t_{SPC}, having a value of 0 to the codeword, c, to make the number of 1s in the transmission data TD an even number, thereby generating the transmission data TD corresponding to the final codeword, (1, 0, 0, 1, 1, 1, 1, 1, 0, 0 (t_{SPC})).

The 1^{st}-X decoder 10-X may generate the counting result N_TEB_X, based on Equation 6.

$$RD = ( \begin{matrix}r 1 \\ r 2 \\ ⋮ \\ r 6 \\ rP 1 \\ rP 2 \\ rP 3 \\ rP 4 \\ rSPC\end{matrix} ) \qquad [ Equation 6 ]$$

$${H}_{seHamm} = [ \begin{matrix}1 & 0 & 0 & 0 & 1 & 0 & 0 & 1 & 1 & 0 & 0 \\ 0 & 1 & 0 & 0 & 1 & 1 & 0 & 1 & 0 & 1 & 0 \\ 0 & 0 & 1 & 0 & 0 & 1 & 1 & 0 & 1 & 0 & 0 \\ 0 & 0 & 0 & 1 & 0 & 0 & 1 & 1 & 0 & 1 & 0 \\ 1 & 1 & 1 & 1 & 1 & 1 & 1 & 1 & 1 & 1 & 1\end{matrix} ]$$

$${Synd}_{T} = {H}_{seHamm} * RD = ( \begin{matrix}Synd \\ SPC\end{matrix} )$$

$$S = \{ 1 , α , {α}^{2} , {α}^{3} , {α}^{4} , {α}^{5} , {α}^{6} , {α}^{7} , {α}^{8} , {α}^{9} \}$$

Here, RD may be reception data in which the error E is in the transmission data TD, Synd_{T} may represent a total syndrome matrix, and Synd may represent the syndrome matrix defined in Equation 4 and may be referred to as a sub syndrome matrix. In addition, S may represent a set having, as an element, each column vector of the parity-check matrix, H_{sHamm}, of the shortened Hamming code in Equation 4. H_{seHamm} may represent a parity-check matrix and may be obtained by changing the structure of the parity-check matrix, H_{sHamm}, in Equation 4. The parity-check matrix, H_{seHamm}, may be obtained by adding a column of 0s after the last column of the parity-check matrix, H_{sHamm}, and adding a row of 1s below the last row of the parity-check matrix, H_{sHamm}. SPC may be the modulo-2 sum of all elements of the reception data RD and may be used to determine whether there are an odd number of transmission error bits in the reception data RD. For example, because the additional bit, t_{SPC}, making the number of 1s in the transmission data TD an even number is added in Equation 5, when SPC is 1, it may mean that there are an odd number of transmission error bits in the reception data RD.

The 1^{st}-X decoder 10-X may calculate the total syndrome matrix, Synd_{T}, by performing modulo-2 multiplication of the reception data RD and the parity-check matrix, H_{seHamm}, in Equation 6, thereby generating the counting result N_TEB_X, based on the value of the SPC and the sub syndrome matrix, Synd, included in the total syndrome matrix, Synd_{T}.

Referring to (a) of FIG. 10, it may be seen that the value of SPC “SPC synd (0 or 1)”, and status of a sub syndrome matrix synd “Hamm synd check” (e.g., whether the sub syndrome matrix synd is included in the set, S, or whether the sub syndrome matrix synd is a zero matrix), are illustrated according to the total number of transmission error bits, the number of transmission error bits in the received additional bit, rSPC, and the number of transmission error bits in a shortened Hamming code encoding-based codeword (r1, r2, . . . , r6, rP1, rP2, rP3, rP4).

For convenience of description, the total number of transmission error bits is expressed as Error (total), the number of transmission error bits in the received additional bit, rSPC, is expressed as Error (SPC), and the number of transmission error bits in the shortened Hamming code encoding-based codeword (r1, r2, . . . , r6, rP1, rP2, rP3, rP4) is expressed as Error (Hamm).

Referring to (a) of FIG. 10, in the case of (0, 0, 0), the value of SPC may be 0 and the sub syndrome matrix, Synd, may be a zero matrix.

In the case of (1, 0, 1), because the value of one bit in the shortened Hamming code encoding-based codeword (r1, r2, . . . , r6, rP1, rP2, rP3, rP4) is changed, the value of SPC may be 1 and the sub syndrome matrix, Synd, may be included in the set, S. In the case of (1, 1, 0), because the value of the received additional bit, rSPC, is changed, the value of SPC may be 1 and the sub syndrome matrix, Synd, may be a zero matrix.

In the case of (2, 0, 2), because the values of two bits in the shortened Hamming code encoding-based codeword (r1, r2, . . . , r6, rP1, rP2, rP3, rP4) are changed, the value of SPC may be 0 and the sub syndrome matrix, Synd, may or may not be included in the set, S. In the case of (2, 1, 1), because the value of the received additional bit, rSPC, is changed and the value of one bit in the shortened Hamming code encoding-based codeword (r1, r2, . . . , r6, rP1, rP2, rP3, rP4) is changed, the value of SPC may be 0 and the sub syndrome matrix, Synd, may be included in the set, S.

In the case of (3, 0, 3), because the values of three bits in the shortened Hamming code encoding-based codeword (r1, r2, . . . , r6, rP1, rP2, rP3, rP4) are changed, the value of SPC may be 1 and the sub syndrome matrix, Synd, may or may not be included in the set, S. In the case of (3, 1, 2), because the value of the received additional bit, rSPC, is changed and the values of two bits in the shortened Hamming code encoding-based codeword (r1, r2, . . . , r6, rP1, rP2, rP3, rP4) are changed, the value of SPC may be 1 and the sub syndrome matrix, Synd, may or may not be included in the set, S.

In the case of (4, 0, 4), because the values of four bits in the shortened Hamming code encoding-based codeword (r1, r2, . . . , r6, rP1, rP2, rP3, rP4) are changed, the value of SPC may be 0 and the sub syndrome matrix, Synd, may or may not be included in the set, S. In the case of (4, 1, 3), because the value of the received additional bit, rSPC, is changed and the values of three bits in the shortened Hamming code encoding-based codeword (r1, r2, . . . , r6, rP1, rP2, rP3, rP4) are changed, the value of SPC may be 0 and the sub syndrome matrix, Synd, may or may not be included in the set, S.

When (a) of FIG. 10 is summarized according to the value of SPC and the status of the sub syndrome matrix, Synd, (b) of FIG. 10 may be obtained. The counting result N_TEB_X obtained by the 1^{st}-X decoder 10-X according to the value of SPC and the status of the sub syndrome matrix, Synd, is illustrated in (b) of FIG. 10.

For convenience of description, the value of SPC is expressed as 1 or 0, and the status of the sub syndrome matrix, Synd, is expressed as 0 (indicating that the sub syndrome matrix, Synd, is a zero matrix), T (indicating that the sub syndrome matrix, Synd, is included in the set, S), or F (indicating that the sub syndrome matrix, Synd, is not included in the set, S).

Referring to (b) of FIG. 10, in the case of (0, 0), the 1^{st}-X decoder 10-X may generate the counting result N_TEB_X indicating that the number of transmission error bits on the data line DQ_X is 0. In other words, when the value of SPC is 0 and the sub syndrome matrix, Synd, is a zero matrix, the 1^{st}-X decoder 10-X may generate the counting result N_TEB_X indicating that the number of transmission error bits on the data line DQ_X is 0.

Referring to (b) of FIG. 10, in the case of (0, T), the 1^{st}-X decoder 10-X may generate the counting result N_TEB_X indicating that the number of transmission error bits on the data line DQ_X is 2. In other words, when the value of SPC is 0 and the sub syndrome matrix, Synd, is included in the set, S, the 1^{st}-X decoder 10-X may generate the counting result N_TEB_X indicating that the number of transmission error bits on the data line DQ_X is 2. In this case, it may be assumed that the smaller the number of transmission error bits, the higher the possibility of occurrence (i.e., the case where the number of transmission error bits is 2 has a higher possibility of occurrence than the case where the number of transmission error bits is 4). The 1^{st}-X decoder 10-X may count the number of transmission error bits as 2 by adopting the case (i.e., (2, 0, 2) or (2, 1, 1)) where the number of transmission error bits is 2 among all possible cases (i.e., (2, 0, 2), (2, 1, 1), (4, 0, 4), and (4, 1, 3)).

Referring to (b) of FIG. 10, in the case of (0, F), the 1^{st}-X decoder 10-X may generate the counting result N_TEB_X indicating that the number of transmission error bits on the data line DQ_X is 2. In other words, when the value of SPC is 0 and the sub syndrome matrix, Synd, is not included in the set, S, the 1^{st}-X decoder 10-X may generate the counting result N_TEB_X indicating that the number of transmission error bits on the data line DQ_X is 2. In this case, it may be assumed that the smaller the number of transmission error bits, the higher the possibility of occurrence (i.e., the case where the number of transmission error bits is 2 has a higher possibility of occurrence than the case where the number of transmission error bits is 4). The 1^{st}-X decoder 10-X may count the number of transmission error bits as 2 by adopting the case (i.e., (2, 0, 2)) where the number of transmission error bits is 2 among all possible cases (i.e., (2, 0, 2), (4, 0, 4), and (4, 1, 3)).

Referring to (b) of FIG. 10, in the case of (1, 0), the 1^{st}-X decoder 10-X may generate the counting result N_TEB_X indicating that the number of transmission error bits on the data line DQ_X is 1. In other words, when the value of SPC is 1 and the sub syndrome matrix, Synd, is a zero matrix, the 1^{st}-X decoder 10-X may generate the counting result N_TEB_X indicating that the number of transmission error bits on the data line DQ_X is 1.

Referring to (b) of FIG. 10, in the case of (1, T), the 1^{st}-X decoder 10-X may generate the counting result N_TEB_X indicating that the number of transmission error bits on the data line DQ_X is 1. In other words, when the value of SPC is 1 and the sub syndrome matrix, Synd, is included in the set, S, the 1^{st}-X decoder 10-X may generate the counting result N_TEB_X indicating that the number of transmission error bits on the data line DQ_X is 1. In this case, it may be assumed that the smaller the number of transmission error bits, the higher the possibility of occurrence (i.e., the case where the number of transmission error bits is 1 has a higher possibility of occurrence than the case where the number of transmission error bits is 3). The 1^{st}-X decoder 10-X may count the number of transmission error bits as 1 by adopting the case (i.e., (1, 0, 1)) where the number of transmission error bits is 1 among all possible cases (i.e., (1, 0, 1), (3, 0, 3), and (3, 1, 2)).

Referring to (b) of FIG. 10, in the case of (1, F), the 1^{st}-X decoder 10-X may generate the counting result N_TEB_X indicating that the number of transmission error bits on the data line DQ_X is 3. In other words, when the value of SPC is 1 and the sub syndrome matrix, Synd, is not included in the set, S, the 1^{st}-X decoder 10-X may generate the counting result N_TEB_X indicating that the number of transmission error bits on the data line DQ_X is 3.

FIG. 11 is a diagram illustrating a decision tree of the 1^{st}-X decoder 10-X, which organizes FIG. 10.

As described above, the 1^{st}-X decoder 10-X may calculate the total syndrome matrix, Synd_{T}, by performing modulo-2 multiplication of the reception data RD and the parity-check matrix, H_{seHamm}, in Equation 6, thereby generating the counting result N_TEB_X, based on the value of SPC and the sub syndrome matrix, Synd, included in the total syndrome matrix, Synd_{T}.

Referring to FIG. 11, the 1^{st}-X decoder 10-X may identify whether the value of SPC is 0 or 1 in operation S21.

When the value of SPC is 0 in operation S21, operation S23 may be performed.

Referring to FIGS. 10 and 11, the 1^{st}-X decoder 10-X may identify whether the sub syndrome matrix, Synd, is a zero matrix in operation S23. When the value of SPC is 0, the 1^{st}-X decoder 10-X may generate the counting result N_TEB_X indicating that the number of transmission error bits on the data line DQ_X is 0 or 2, based on whether the sub syndrome matrix, Synd, is a zero matrix.

When the sub syndrome matrix, Synd, is a zero matrix in operation S23, the 1^{st}-X decoder 10-X may count, as 0, the number of transmission error bits on the data line DQ_X. Accordingly, the 1^{st}-X decoder 10-X may generate the counting result N_TEB_X indicating that the number of transmission error bits on the data line DQ_X is 0. In other words, when the value of SPC is 0 and the sub syndrome matrix, Synd, is a zero matrix, the 1^{st}-X decoder 10-X may generate the counting result N_TEB_X indicating that the number of transmission error bits on the data line DQ_X is 0.

When the sub syndrome matrix, Synd, is not a zero matrix in operation S23, the 1^{st}-X decoder 10-X may count, as 2, the number of transmission error bits on the data line DQ_X. Accordingly, the 1^{st}-X decoder 10-X may generate the counting result N_TEB_X indicating that the number of transmission error bits on the data line DQ_X is 2. In other words, when the value of SPC is 0 and the sub syndrome matrix, Synd, is not a zero matrix, the 1^{st}-X decoder 10-X may generate the counting result N_TEB_X indicating that the number of transmission error bits on the data line DQ_X is 2.

When the value of SPC is 1 in operation S21, operation S25 may be performed.

Referring to FIG. 11, the 1^{st}-X decoder 10-X may identify the status of the sub syndrome matrix, Synd, in operation S25. In other words, the 1^{st}-X decoder 10-X may identify whether the sub syndrome matrix, Synd, is a zero matrix or is an element included in the set, S. When the value of SPC is 1, the 1^{st}-X decoder 10-X may generate the counting result N_TEB_X indicating that the number of transmission error bits on the data line DQ_X is 1 or 3, based on the status of the sub syndrome matrix, Synd.

When the sub syndrome matrix, Synd, is a zero matrix or is an element included in the set, S, in operation S25, the 1^{st}-X decoder 10-X may count, as 1, the number of transmission error bits on the data line DQ_X. Accordingly, the 1^{st}-X decoder 10-X may generate the counting result N_TEB_X indicating that the number of transmission error bits on the data line DQ_X is 1. In other words, when the value of SPC is 1 and the sub syndrome matrix, Synd, is a zero matrix or is an element included in the set, S, the 1^{st}-X decoder 10-X may generate the counting result N_TEB_X indicating that the number of transmission error bits on the data line DQ_X is 1.

When the sub syndrome matrix, Synd, is neither a zero matrix nor an element included in the set, S, in operation S25, the 1^{st}-X decoder 10-X may count, as 3, the number of transmission error bits on the data line DQ_X. Accordingly, the 1^{st}-X decoder 10-X may generate the counting result N_TEB_X indicating that the number of transmission error bits on the data line DQ_X is 3. In other words, when the value of SPC is 1 and the sub syndrome matrix, Synd, is neither a zero matrix nor an element included in the set, S, the 1^{st}-X decoder 10-X may generate the counting result N_TEB_X indicating that the number of transmission error bits on the data line DQ_X is 3.

In an implementation, the 1^{st}-X decoder 10-X may store all elements of the set, S, in advance as an LUT. The 1^{st}-X decoder 10-X may compare the sub syndrome matrix, Synd, with all elements of the set, S, stored in advance as an LUT and may generate the counting result N_TEB_X corresponding to the number of transmission error bits on the data line DQ_X.

A method of generating, performed by the encoder 30, the transmission data TD by performing shortened BCH code encoding on the sub data DATA_S and a method of generating, performed by the 1^{st}-X decoder 10-X, the counting result N_TEB_X, which corresponds to the number of transmission error bits on the data line DQ_X, by decoding the reception data RD will be described below with reference to FIGS. 12 to 14.

A method of counting, performed by the 1^{st}-X decoder 10-X, up to three transmission error bits in the reception data RD is described with reference to FIG. 12.

The transmission data TD may correspond to a codeword that has undergone shortened BCH code encoding by the encoder 30. The reception data RD may correspond to data (or a codeword) in which the error E is in the transmission data TD.

It may be assumed that an original BCH code is a (15, 11) BCH code having an error correction capability “t” of 2 and a shortened BCH code is a (10, 6) BCH code in which five data bits in the original BCH code are not used. In other words, in the original BCH code (i.e., the (15, 11) BCH code having the error correction capability “t” of 2), the total number of bits in a codeword, n, may be 15, the number of data bits, k, may be 11, and the number of parity bits, m, may be 4. In the shortened BCH code (i.e., the (10, 6) BCH code having the error correction capability “t” of 2), the total number of bits in a codeword, n′, may be 10, the number of data bits, k′, may be 6, and the number of parity bits, m, may be 4. The shortened BCH code and the original BCH code may have the same number of parity bits, “m”. However, the present disclosure is not limited thereto. According to implementations, parameters may be variously changed.

The encoder 30 may generate a codeword that has undergone shortened BCH code encoding.

For example, the encoder 30 may generate a codeword, based on Equation 7.

$${G}_{shortened} = ( \begin{matrix}1 & 0 & 0 & 0 & 0 & 0 & 1 & 0 & 1 & 1 \\ 0 & 1 & 0 & 0 & 0 & 0 & 1 & 1 & 0 & 1 \\ 0 & 0 & 1 & 0 & 0 & 0 & 1 & 1 & 1 & 0 \\ 0 & 0 & 0 & 1 & 0 & 0 & 0 & 1 & 1 & 1 \\ 0 & 0 & 0 & 0 & 1 & 0 & 1 & 0 & 0 & 1 \\ 0 & 0 & 0 & 0 & 0 & 1 & 1 & 1 & 0 & 0\end{matrix} ) \qquad [ Equation 7 ]$$

$$c = m * {G}_{shortened}$$

Here, G_{shortened} may represent a generator matrix of the shortened BCH code of size 6×10, “c”, as a codeword of size 1×10, may correspond to the transmission data TD, and “m”, as a data vector of size 1×6, may correspond to the sub data DATA_S. For example, the data vector may be represented as m=(1,0,1,1,0,1).

The 1^{st}-X decoder 10-X may generate the counting result N_TEB_X, based on the received codeword. The received codeword may be provided by the data line DQ_X and may have undergone shortened BCH code encoding.

For example, the 1^{st}-X decoder 10-X may generate the counting result N_TEB_X, based on Equation 8.

$${H}_{sBCH} = [ \begin{matrix}1 & α & {α}^{2} & {α}^{3} & {α}^{4} & {α}^{5} & {α}^{6} & {α}^{7} & {α}^{8} & {α}^{9} \\ 1 & {α}^{3} & {α}^{6} & {α}^{9} & {α}^{12} & 1 & {α}^{3} & {α}^{6} & {α}^{9} & {α}^{12}\end{matrix} ] = [ \begin{matrix}1 & 0 & 0 & 0 & 1 & 0 & 0 & 1 & 1 & 0 \\ 0 & 1 & 0 & 0 & 1 & 1 & 0 & 1 & 0 & 1 \\ 0 & 0 & 1 & 0 & 0 & 1 & 1 & 0 & 1 & 0 \\ 0 & 0 & 0 & 1 & 0 & 0 & 1 & 1 & 0 & 1 \\ 1 & 0 & 1 & 0 & 1 & 1 & 0 & 1 & 0 & 1 \\ 0 & 0 & 1 & 1 & 1 & 0 & 0 & 1 & 1 & 1 \\ 0 & 0 & 0 & 0 & 1 & 0 & 0 & 0 & 0 & 1 \\ 0 & 1 & 1 & 1 & 1 & 0 & 1 & 1 & 1 & 1\end{matrix} ] \qquad [ Equation 8 ]$$

$$RD = ( \begin{matrix}r 1 \\ r 2 \\ ⋮ \\ r 6 \\ rP 1 \\ rP 2 \\ rP 3 \\ rP 4\end{matrix} )$$

$$Synd = {H}_{sBCH} * RD = ( \begin{matrix}Synd 1 \\ Synd 2\end{matrix} )$$

$${S}_{1} = \{ 1 , α , {α}^{2} , {α}^{3} , {α}^{4} , {α}^{5} , {α}^{6} , {α}^{7} , {α}^{8} , {α}^{9} \}$$

$${S}_{2} = \{ 1 , {α}^{3} , {α}^{6} , {α}^{9} , {α}^{12} \}$$

Here, α may represent a primitive element in the Galois field of order 2^{m=4}, α and the powers of α may be transformed into different binary vectors of length 4, H_{sBCH} may represent a parity-check matrix of the shortened BCH code, RD may be reception data in which the error E is in the transmission data TD, Synd may represent a syndrome matrix, S₁ may represent a set having, as an element, each column vector of the first row of the parity-check matrix, H_{sBCH}, of the shortened BCH code represented with α, and S₂ may represent a set having, as an element, each column vector of the second row of the parity-check matrix, H_{sBCH}, of the shortened BCH code represented with a. The syndrome matrix, Synd, may include a first sub syndrome matrix, Synd1, and a second sub syndrome matrix, Synd2. The first sub syndrome matrix, Synd1, may be a result of performing modulo-2 multiplication of the reception data RD and the first row of the parity-check matrix of the shortened BCH code represented with α, and the second sub syndrome matrix, Synd2, may be a result of performing modulo-2 multiplication of the reception data RD and the second row of the parity-check matrix of the shortened BCH code represented with a.

Referring to FIG. 12 and Equation 8, the 1^{st}-X decoder 10-X may calculate the syndrome matrix, Synd, by performing modulo-2 multiplication of the reception data RD and the parity-check matrix, H_{sBCH}, of the shortened BCH code and identify whether the syndrome matrix, Synd, is a zero matrix in operation S31.

When the syndrome matrix, Synd, is a zero matrix in operation S31, the 1^{st}-X decoder 10-X may count, as 0, the number of transmission error bits on the data line DQ_X. Accordingly, the 1^{st}-X decoder 10-X may generate the counting result N_TEB_X indicating that the number of transmission error bits on the data line DQ_X is 0.

When the syndrome matrix, Synd, is not a zero matrix in operation S31, operation S33 may be performed.

Referring to FIG. 12 and Equation 8, the 1^{st}-X decoder 10-X may identify whether the first sub syndrome matrix, Synd1, included in the syndrome matrix, Synd, is an element included in the set, S₁, or whether the second sub syndrome matrix, Synd2, included in the syndrome matrix, Synd, is an element included in the set, S₂.

When the syndrome matrix, Synd, is not a zero matrix, the 1^{st}-X decoder 10-X may count transmission error bits as 1, 2, or 3, based on whether the first sub syndrome matrix, Synd1, included in the syndrome matrix, Synd, is an element included in the set, S₁, or whether the second sub syndrome matrix, Synd2, included in the syndrome matrix, Synd, is an element included in the set, S₂.

When the first sub syndrome matrix, Synd1, is an element included in the set, S₁, and the second sub syndrome matrix, Synd2, is an element included in the set, S₂, in operation S33, the 1^{st}-X decoder 10-X may count, as 1, the number of transmission errors on the data line DQ_X. Accordingly, the 1^{st}-X decoder 10-X may generate the counting result N_TEB_X indicating that the number of transmission error bits on the data line DQ_X is 1. This is because, when the number of transmission error bits in the reception data RD is 1, the syndrome matrix, Synd, may correspond to one of ten column vectors included in the parity-check matrix, H_{sBCH}, of the shortened BCH code.

When the second sub syndrome matrix, Synd2, is not an element included in the set, S₂, in operation S33, the 1^{st}-X decoder 10-X may count, as 2, the number of transmission errors on the data line DQ_X. Accordingly, the 1^{st}-X decoder 10-X may generate the counting result N_TEB_X indicating that the number of transmission error bits on the data line DQ_X is 2. This is because, when the number of transmission error bits in the reception data RD is 2, the second sub syndrome matrix, Synd2, may not be calculated as the elements (1, α³, α⁶, α⁹, α¹²) of the set, S₂.

When the first sub syndrome matrix, Synd1, is not an element included in the set, S1, and the second sub syndrome matrix, Synd2, is an element included in the set, S₂, in operation S33, the 1^{st}-X decoder 10-X may count, as 3, the number of transmission errors on the data line DQ_X. Accordingly, the 1^{st}-X decoder 10-X may generate the counting result N_TEB_X indicating that the number of transmission error bits on the data line DQ_X is 3. The condition of this case (i.e., the first sub syndrome matrix, Synd1, is not an element included in the set, S₁, and the second sub syndrome matrix, Synd2, is an element included in the set, S₂) may be a case other the condition of counting 2 and the condition of counting 1, which have been described above. In this case, the number of transmission error bits in the reception data RD may be counted as 3.

In an implementation, the 1^{st}-X decoder 10-X may store all elements of each of the set, S₁, and the set, S₂, in advance as an LUT. The 1^{st}-X decoder 10-X may compare the first sub syndrome matrix, Synd1, of the syndrome matrix, Synd, with all elements of the set, S₁, stored in advance as an LUT and the second sub syndrome matrix, Synd2, of the syndrome matrix, Synd, with all elements of the set, S₂, stored in advance as an LUT and may generate the counting result N_TEB_X corresponding to the number of transmission error bits on the data line DQ_X.

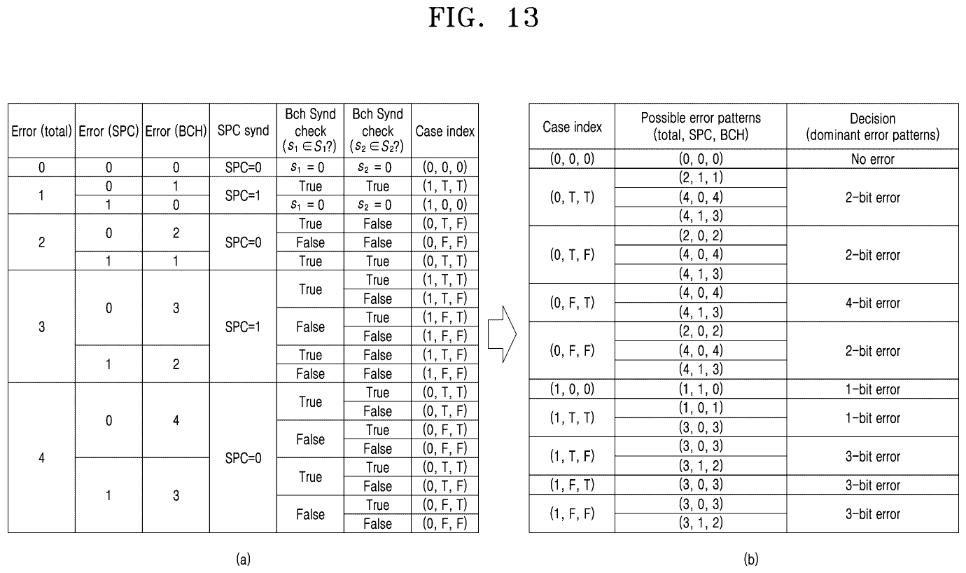

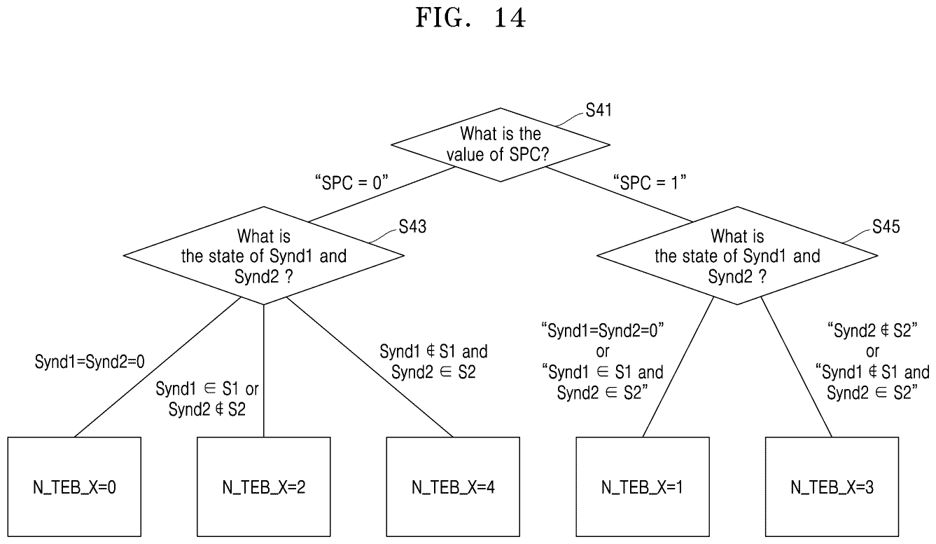

A method of counting, performed by the 1^{st}-X decoder 10-X, up to four transmission error bits in the reception data RD corresponding to a codeword based on shortened BCH code encoding is described with reference to FIGS. 13 and 14.

The encoder 30 may generate a codeword that has undergone shortened BCH code encoding.

For example, the encoder 30 may generate a codeword that has undergone shortened BCH code encoding, based on Equation 7 described above and Equation 9 below.

$$TD = ( \begin{matrix}{c}^{T} \\ tSPC\end{matrix} ) = ( \begin{matrix}t 1 \\ t 2 \\ ⋮ \\ t 6 \\ tP 1 \\ tP 2 \\ tP 3 \\ tP 4 \\ tSPC\end{matrix} ) \qquad [ Equation 9 ]$$

Here, TD may represent transmission data, “c” may represent a codeword that has undergone shortened BCH code encoding described in Equation 7, and t_{SPC} may represent an additional bit that makes the number of 1s in the transmission data TD an even number and may have a value of 1 or 0.

In other words, the encoder 30 may generate a final codeword by adding an additional bit to the codeword that has undergone shortened BCH code encoding such that the number of 1s in the codeword becomes an even number.

For example, when the codeword, c, that has undergone shortened BCH code encoding is (1, 0, 0, 1, 1, 1, 1, 1, 1), the number of 1s in the codeword, c, is an odd number. The encoder 30 may add the additional bit, t_{SPC}, having a value of 1 to the codeword, c, to make the number of 1s in the transmission data TD an even number, thereby generating the transmission data TD corresponding to the final codeword, (1, 0, 0, 1, 1, 1, 1, 1, 1, 1 (t_{SPC})). For example, when the codeword, c, that has undergone shortened BCH code encoding is (1, 0, 0, 1, 1, 1, 1, 1, 0), the number of 1s in the codeword, c, is an even number. The encoder 30 may add the additional bit, t_{SPC}, having a value of 0 to the codeword, c, to make the number of 1s in the transmission data TD an even number, thereby generating the transmission data TD corresponding to the final codeword, (1, 0, 0, 1, 1, 1, 1, 1, 0, 0 (t_{SPC})).

The 1^{st}-X decoder 10-X may generate the counting result N_TEB_X, based on Equation 10.

$$RD = ( \begin{matrix}r 1 \\ r 2 \\ ⋮ \\ r 6 \\ rP 1 \\ rP 2 \\ rP 3 \\ rP 4 \\ rSPC\end{matrix} ) \qquad [ Equation 10 ]$$

$${H}_{seBCH} = [ \begin{matrix}1 & 0 & 0 & 0 & 1 & 0 & 0 & 1 & 1 & 0 & 0 \\ 0 & 1 & 0 & 0 & 1 & 1 & 0 & 1 & 0 & 1 & 0 \\ 0 & 0 & 1 & 0 & 0 & 1 & 1 & 0 & 1 & 0 & 0 \\ 0 & 0 & 0 & 1 & 0 & 0 & 1 & 1 & 0 & 1 & 0 \\ 1 & 0 & 1 & 0 & 1 & 1 & 0 & 1 & 0 & 1 & 0 \\ 0 & 0 & 1 & 1 & 1 & 0 & 0 & 1 & 1 & 1 & 0 \\ 0 & 0 & 0 & 0 & 1 & 0 & 0 & 0 & 0 & 1 & 0 \\ 0 & 1 & 1 & 1 & 1 & 0 & 1 & 1 & 1 & 1 & 0 \\ 1 & 1 & 1 & 1 & 1 & 1 & 1 & 1 & 1 & 1 & 1\end{matrix} ]$$

$${Synd}_{T} = {H}_{seHamm} * RD = ( \begin{matrix}Synd 1 \\ Synd 2 \\ SPC\end{matrix} )$$

$${S}_{1} = \{ 1 , α , {α}^{2} , {α}^{3} , {α}^{4} , {α}^{5} , {α}^{6} , {α}^{7} , {α}^{8} , {α}^{9} \}$$

$${S}_{2} = \{ 1 , {α}^{3} , {α}^{6} , {α}^{9} , {α}^{12} \}$$

Here, RD may be reception data in which the error E is in the transmission data TD, Synd_{T} may represent a total syndrome matrix, Synd1 may represent the first syndrome matrix in Equation 8, Synd2 may represent a second syndrome matrix in Equation 8, S₁ may represent a set having, as an element, each column vector of the first row of the parity-check matrix, H_{sBCH}, of the shortened BCH code represented with α in Equation 8, and S₂ may represent a set having, as an element, each column vector of the second row of the parity-check matrix, H_{sBCH}, of the shortened BCH code represented with α in Equation 8. H_{seBCH} may represent a parity-check matrix and may be obtained by changing the structure of the parity-check matrix, H_{sBCH}, in Equation 8. The parity-check matrix, H_{seBCH}, may be obtained by adding a column of 0s after the last column of the parity-check matrix, H_{sBCH}, and adding a row of 1s below the last row of the parity-check matrix, H_{sBCH}. SPC may be the modulo-2 sum of all elements of the reception data RD and may be used to determine whether there are an odd number of transmission error bits in the reception data RD. For example, because the additional bit, t_{SPC}, making the number of 1s in the transmission data TD an even number is added in Equation 9, when SPC is 1, it may mean that there are an odd number of transmission error bits in the reception data RD.

The 1^{st}-X decoder 10-X may calculate the total syndrome matrix, Synd_{T}, by performing modulo-2 multiplication of the reception data RD and the parity-check matrix, H_{seBCH}, in Equation 10, thereby generating the counting result N_TEB_X, based on the value of the SPC, the first sub syndrome matrix, Synd1, included in the total syndrome matrix, Synd, and the second sub syndrome matrix, Synd2, included in the total syndrome matrix, Synd_{T}.

Referring to (a) of FIG. 13, it may be seen that the value of SPC “SPC synd (0 or 1)”, status of the first sub syndrome matrix, Synd1, (e.g., whether the first sub syndrome matrix, Synd1, is included in the set, S₁, or whether the first sub syndrome matrix, Synd1, is a zero matrix), and status of the second sub syndrome matrix, Synd2, (e.g., whether the second sub syndrome matrix, Synd2, is included in the set, S₂, or whether the second sub syndrome matrix, Synd2, is a zero matrix), are illustrated according to the total number of transmission error bits, the number of transmission error bits in the received additional bit, rSPC, and the number of transmission error bits in a shortened BCH code encoding-based codeword (r1, r2, . . . , r6, rP1, rP2, rP3, rP4).

For convenience of description, the total number of transmission error bits is expressed as Error (total), the number of transmission error bits in the received additional bit, rSPC, is expressed as Error (SPC), and the number of transmission error bits in the shortened BCH code encoding-based codeword (r1, r2, . . . , r6, rP1, rP2, rP3, rP4) is expressed as Error (BCH).

Referring to (a) of FIG. 13, in the case of (0, 0, 0), the value of SPC may be 0 and each of the first sub syndrome matrix, Synd1, and the second sub syndrome matrix, Synd2, may be a zero matrix.

In the case of (1, 0, 1), because the value of one bit in the shortened BCH code encoding-based codeword (r1, r2, . . . , r6, rP1, rP2, rP3, rP4) is changed, the value of SPC may be 1, the first sub syndrome matrix, Synd1, may be included in the set, S₁, and the second sub syndrome matrix, Synd2, may be included in the set, S₂. In the case of (1, 1, 0), because the value of the received additional bit, rSPC, is changed, the value of SPC may be 1 and each of the first sub syndrome matrix, Synd1, and the second sub syndrome matrix, Synd2, may be a zero matrix.

In the case of (2, 0, 2), because the values of two bits in the shortened BCH code encoding-based codeword (r1, r2, . . . , r6, rP1, rP2, rP3, rP4) are changed, the value of SPC may be 0, and the first sub syndrome matrix, Synd1, may be included in the set, S₁, and the second sub syndrome matrix, Synd2, may not be included in the set, S₂, or the first sub syndrome matrix, Synd1, may not be included in the set, S₁, and the second sub syndrome matrix, Synd2, may be included in the set, S₂, or the first sub syndrome matrix, Synd1, may be included in the set, S₁, and the second sub syndrome matrix, Synd2, may be included in the set, S₂. In the case of (2, 1, 1), because the value of the received additional bit, rSPC, is changed and the value of one bit in the shortened BCH code encoding-based codeword (r1, r2, . . . , r6, rP1, rP2, rP3, rP4) is changed, the value of SPC may be 0, the first sub syndrome matrix, Synd1, may be included in the set, S₁, and the second sub syndrome matrix, Synd2, may be included in the set, S₂.

In the case of (3, 0, 3), because the values of three bits in the shortened BCH code encoding-based codeword (r1, r2, . . . , r6, rP1, rP2, rP3, rP4) are changed, the value of SPC may be 1, the first sub syndrome matrix, Synd1, may or may not be included in the set, S₁, and the second sub syndrome matrix, Synd2, may or may not be included in the set, S₂. In the case of (3, 1, 2), because the value of the received additional bit, rSPC, is changed and the values of two bits in the shortened BCH code encoding-based codeword (r1, r2, . . . , r6, rP1, rP2, rP3, rP4) are changed, the value of SPC may be 1, and the first sub syndrome matrix, Synd1, may be included in the set, S₁, and the second sub syndrome matrix, Synd2, may not be included in the set, S₂, or the first sub syndrome matrix, Synd1, may not be included in the set, S₁, and the second sub syndrome matrix, Synd2, may not be included in the set, S₂.

In the case of (4, 0, 4), because the values of four bits in the shortened BCH code encoding-based codeword (r1, r2, . . . , r6, rP1, rP2, rP3, rP4) are changed, the value of SPC may be 0, the first sub syndrome matrix, Synd1, may or may not be included in the set, S₁, and the second sub syndrome matrix, Synd2, may or may not be included in the set, S₂. In the case of (4, 1, 3), because the value of the received additional bit, rSPC, is changed and the values of three bits in the shortened BCH code encoding-based codeword (r1, r2, . . . , r6, rP1, rP2, rP3, rP4) are changed, the value of SPC may be 0, the first sub syndrome matrix, Synd1, may or may not be included in the set, S₁, and the second sub syndrome matrix, Synd2, may or may not be included in the set, S₂.

When (a) of FIG. 13 is summarized according to the value of SPC, the status of the first sub syndrome matrix, Synd1, and the status of the second sub syndrome matrix, Synd2, (b) of FIG. 13 may be obtained. The counting result N_TEB_X obtained by the 1^{st}-X decoder 10-X according to the value of SPC, the first sub syndrome matrix, Synd1, and the second sub syndrome matrix, Synd2, is illustrated in (b) of FIG. 13.

For convenience of description, the value of SPC is expressed as 1 or 0, the status of the first sub syndrome matrix, Synd1, is expressed as 0 (indicating that the first sub syndrome matrix, Synd1, is a zero matrix), T (indicating that the first sub syndrome matrix, Synd1, is included in the set, S₁), or F (indicating that the first sub syndrome matrix, Synd1, is not included in the set, S₁), and the status of the second sub syndrome matrix, Synd2, is expressed as 0 (indicating that the second sub syndrome matrix, Synd2, is a zero matrix), T (indicating that the second sub syndrome matrix, Synd2, is included in the set, S₂), or F (indicating that the second sub syndrome matrix, Synd2, is not included in the set, S₂).

Referring to (b) of FIG. 13, in the case of (0, 0, 0), the 1^{st}-X decoder 10-X may generate the counting result N_TEB_X indicating that the number of transmission error bits on the data line DQ_X is 0. In other words, when the value of SPC is 0 and each of the first sub syndrome matrix, Synd1, and the second sub syndrome matrix, Synd2, is a zero matrix, the 1^{st}-X decoder 10-X may generate the counting result N_TEB_X indicating that the number of transmission error bits on the data line DQ_X is 0.

Referring to (b) of FIG. 13, in the case of (0, T, T), the 1^{st}-X decoder 10-X may generate the counting result N_TEB_X indicating that the number of transmission error bits on the data line DQ_X is 2. In other words, when the value of SPC is 0, the first sub syndrome matrix, Synd1, is included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 2. In this case, it may be assumed that the smaller the number of transmission error bits, the higher the possibility of occurrence (i.e., the case where the number of transmission error bits is 2 has a higher possibility of occurrence than the case where the number of transmission error bits is 4). The 1^{st}-X decoder 10-X may count the number of transmission error bits as 2 by adopting the case (i.e., (2, 1, 1)) where the number of transmission error bits is 2 among all possible cases (i.e., (2, 1, 1), (4, 0, 4), and (4, 1, 3)).

Referring to (b) of FIG. 13, in the case of (0, T, F), the 1^{st}-X decoder 10-X may generate the counting result N_TEB_X indicating that the number of transmission error bits on the data line DQ_X is 2. In other words, when the value of SPC is 0, the first sub syndrome matrix, Synd1, is included in the set, S₁, and the second sub syndrome matrix, Synd2, is not included in the set, S₂, the 1^{st}-X decoder 10-X may generate the counting result N_TEB_X indicating that the number of transmission error bits on the data line DQ_X is 2. In this case, it may be assumed that the smaller the number of transmission error bits, the higher the possibility of occurrence (i.e., the case where the number of transmission error bits is 2 has a higher possibility of occurrence than the case where the number of transmission error bits is 4). The 1^{st}-X decoder 10-X may count the number of transmission error bits as 2 by adopting the case (i.e., (2, 0, 2)) where the number of transmission error bits is 2 among all possible cases (i.e., (2, 0, 2), (4, 0, 4), and (4, 1, 3)).

Referring to (b) of FIG. 13, in the case of (0, F, T), the 1^{st}-X decoder 10-X may generate the counting result N_TEB_X indicating that the number of transmission error bits on the data line DQ_X is 4. In other words, when the value of SPC is 0, the first sub syndrome matrix, Synd1, is not included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 4.

Referring to (b) of FIG. 13, in the case of (0, F, F), the 1^{st}-X decoder 10-X may generate the counting result N_TEB_X indicating that the number of transmission error bits on the data line DQ_X is 2. In other words, when the value of SPC is 0, the first sub syndrome matrix, Synd1, is not included in the set, S₁, and the second sub syndrome matrix, Synd2, is not included in the set, S₂, the 1^{st}-X decoder 10-X may generate the counting result N_TEB_X indicating that the number of transmission error bits on the data line DQ_X is 2. In this case, it may be assumed that the smaller the number of transmission error bits, the higher the possibility of occurrence (i.e., the case where the number of transmission error bits is 2 has a higher possibility of occurrence than the case where the number of transmission error bits is 4). The 1^{st}-X decoder 10-X may count the number of transmission error bits as 2 by adopting the case (i.e., (2, 0, 2)) where the number of transmission error bits is 2 among all possible cases (i.e., (2, 0, 2), (4, 0, 4), and (4, 1, 3)).

Referring to (b) of FIG. 13, in the case of (1, 0, 0), the 1^{st}-X decoder 10-X may generate the counting result N_TEB_X indicating that the number of transmission error bits on the data line DQ_X is 1. In other words, when the value of SPC is 1 and each of the first sub syndrome matrix, Synd1, and the second sub syndrome matrix, Synd2, is a zero matrix, the 1^{st}-X decoder 10-X may generate the counting result N_TEB_X indicating that the number of transmission error bits on the data line DQ_X is 1.

Referring to (b) of FIG. 13, in the case of (1, T, T), the 1^{st}-X decoder 10-X may generate the counting result N_TEB_X indicating that the number of transmission error bits on the data line DQ_X is 1. In other words, when the value of SPC is 1, the first sub syndrome matrix, Synd1, is included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 1. In this case, it may be assumed that the smaller the number of transmission error bits, the higher the possibility of occurrence (i.e., the case where the number of transmission error bits is 1 has a higher possibility of occurrence than the case where the number of transmission error bits is 3). The 1^{st}-X decoder 10-X may count the number of transmission error bits as 1 by adopting the case (i.e., (1, 0, 1)) where the number of transmission error bits is 1 among all possible cases (i.e., (1, 0, 1) and (3, 0, 3)).

Referring to (b) of FIG. 13, in the case of (1, T, F), the 1^{st}-X decoder 10-X may generate the counting result N_TEB_X indicating that the number of transmission error bits on the data line DQ_X is 3. In other words, when the value of SPC is 1, the first sub syndrome matrix, Synd1, is included in the set, S₁, and the second sub syndrome matrix, Synd2, is not included in the set, S₂, the 1^{st}-X decoder 10-X may generate the counting result N_TEB_X indicating that the number of transmission error bits on the data line DQ_X is 3.

Referring to (b) of FIG. 13, in the case of (1, F, T), the 1^{st}-X decoder 10-X may generate the counting result N_TEB_X indicating that the number of transmission error bits on the data line DQ_X is 3. In other words, when the value of SPC is 0, the first sub syndrome matrix, Synd1, is not included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 3.

Referring to (b) of FIG. 13, in the case of (1, F, F), the 1^{st}-X decoder 10-X may generate the counting result N_TEB_X indicating that the number of transmission error bits on the data line DQ_X is 3. In other words, when the value of SPC is 1, the first sub syndrome matrix, Synd1, is not included in the set, S₁, and the second sub syndrome matrix, Synd2, is not included in the set, S₂, the 1^{st}-X decoder 10-X may generate the counting result N_TEB_X indicating that the number of transmission error bits on the data line DQ_X is 3.

FIG. 14 is a diagram illustrating a decision tree of the 1^{st}-X decoder 10-X, which organizes FIG. 13.

As described above, the 1^{st}-X decoder 10-X may calculate the total syndrome matrix, Synd_{T}, by performing modulo-2 multiplication of the reception data RD and the parity-check matrix, H_{seBCH}, in Equation 10, thereby generating the counting result N_TEB_X, based on the value of SPC and the first sub syndrome matrix, Synd1, and the second sub syndrome matrix, Synd2, which are included in the total syndrome matrix, Synd_{T}.

Referring to FIG. 14, the 1^{st}-X decoder 10-X may identify whether the value of SPC is 0 or 1 in operation S41.

When the value of SPC is 0 in operation S41, operation S43 may be performed.

Referring to FIGS. 13 and 14, the 1^{st}-X decoder 10-X may identify the status of the first sub syndrome matrix, Synd1, and the status of the second sub syndrome matrix, Synd2, in operation S43. When the value of SPC is 0, the 1^{st}-X decoder 10-X may generate the counting result N_TEB_X indicating that the number of transmission error bits on the data line DQ_X is 0, 2, or 4, based on the status of the first sub syndrome matrix, Synd1, and the status of the second sub syndrome matrix, Synd2.

When each of the first sub syndrome matrix, Synd1, and the second sub syndrome matrix, Synd2, is a zero matrix in operation S43, the 1^{st}-X decoder 10-X may count, as 0, the number of transmission error bits on the data line DQ_X. Accordingly, the 1^{st}-X decoder 10-X may generate the counting result N_TEB_X indicating that the number of transmission error bits on the data line DQ_X is 0. In other words, when the value of SPC is 0 and each of the first sub syndrome matrix, Synd1, and the second sub syndrome matrix, Synd2, is a zero matrix, the 1^{st}-X decoder 10-X may generate the counting result N_TEB_X indicating that the number of transmission error bits on the data line DQ_X is 0.

When the first sub syndrome matrix, Synd1, is included in the set, S₁, or the second sub syndrome matrix, Synd2, is not included in the set, S₂, in operation S43, the 1^{st}-X decoder 10-X may count, as 2, the number of transmission error bits on the data line DQ_X. Accordingly, the 1^{st}-X decoder 10-X may generate the counting result N_TEB_X indicating that the number of transmission error bits on the data line DQ_X is 2. In other words, when the value of SPC is 0 and the first sub syndrome matrix, Synd1, is included in the set, S₁, or the second sub syndrome matrix, Synd2, is not included in the set, S₂, the 1^{st}-X decoder 10-X may generate the counting result N_TEB_X indicating that the number of transmission error bits on the data line DQ_X is 2.

When the first sub syndrome matrix, Synd1, is not included in the set, S₁, and the second sub syndrome matrix, Synd2, is included in the set, S₂, in operation S43, the 1^{st}-X decoder 10-X may count, as 4, the number of transmission error bits on the data line DQ_X. Accordingly, the 1^{st}-X decoder 10-X may generate the counting result N_TEB_X indicating that the number of transmission error bits on the data line DQ_X is 4. In other words, when the value of SPC is 0, the first sub syndrome matrix, Synd1, is not included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 4.

When the value of SPC is 1 in operation S41, operation S45 may be performed.

Referring to FIGS. 13 and 14, the 1^{st}-X decoder 10-X may identify the status of the first sub syndrome matrix, Synd1, and the status of the second sub syndrome matrix, Synd2, in operation S45. When the value of SPC is 1, the 1^{st}-X decoder 10-X may generate the counting result N_TEB_X indicating that the number of transmission error bits on the data line DQ_X is 1 or 3, based on the status of the first sub syndrome matrix, Synd1, and the status of the second sub syndrome matrix, Synd2.

When each of the first sub syndrome matrix, Synd1, and the second sub syndrome matrix, Synd2, is a zero matrix or when the first sub syndrome matrix, Synd1, is included in the set, S₁, and the second sub syndrome matrix, Synd2, is included in the set, S₂, in operation S45, the 1^{st}-X decoder 10-X may count, as 1, the number of transmission error bits on the data line DQ_X. Accordingly, the 1^{st}-X decoder 10-X may generate the counting result N_TEB_X indicating that the number of transmission error bits on the data line DQ_X is 1. In other words, when the value of SPC is 1 and each of the first sub syndrome matrix, Synd1, and the second sub syndrome matrix, Synd2, is a zero matrix or when the value of SPC is 1, the first sub syndrome matrix, Synd1, is included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 1.

When the second sub syndrome matrix, Synd2, is not included in the set, S₂, or when the first sub syndrome matrix, Synd1, is not included in the set, S₁, and the second sub syndrome matrix, Synd2, is included in the set, S₂, in operation S45, the 1^{st}-X decoder 10-X may count, as 3, the number of transmission error bits on the data line DQ_X. Accordingly, the 1^{st}-X decoder 10-X may generate the counting result N_TEB_X indicating that the number of transmission error bits on the data line DQ_X is 3. In other words, when the value of SPC is 1 and the second sub syndrome matrix, Synd2, is not included in the set, S₂, or when the value of SPC is 1, the first sub syndrome matrix, Synd1, is not included in the set, S₁, and the second sub syndrome matrix, Synd2, is included in the set, S₂, the 1^{st}-X decoder 10-X may generate the counting result N_TEB_X indicating that the number of transmission error bits on the data line DQ_X is 3.

In an implementation, the 1^{st}-X decoder 10-X may store all elements of the set, S, in advance as an LUT. The 1^{st}-X decoder 10-X may compare the sub syndrome matrix, Synd, with all elements of the set, S, stored in advance as an LUT and may generate the counting result N_TEB_X corresponding to the number of transmission error bits on the data line DQ_X.

In an implementation, the 1^{st}-X decoder 10-X may store all elements of each of the set, S₁, and the set, S₂, in advance as an LUT. The 1^{st}-X decoder 10-X may compare the first sub syndrome matrix, Synd1, of the syndrome matrix, Synd, with all elements of the set, S₁, stored in advance as an LUT and the second sub syndrome matrix, Synd2, of the syndrome matrix, Synd, with all elements of the set, S₂, stored in advance as an LUT and may generate the counting result N_TEB_X corresponding to the number of transmission error bits on the data line DQ_X.

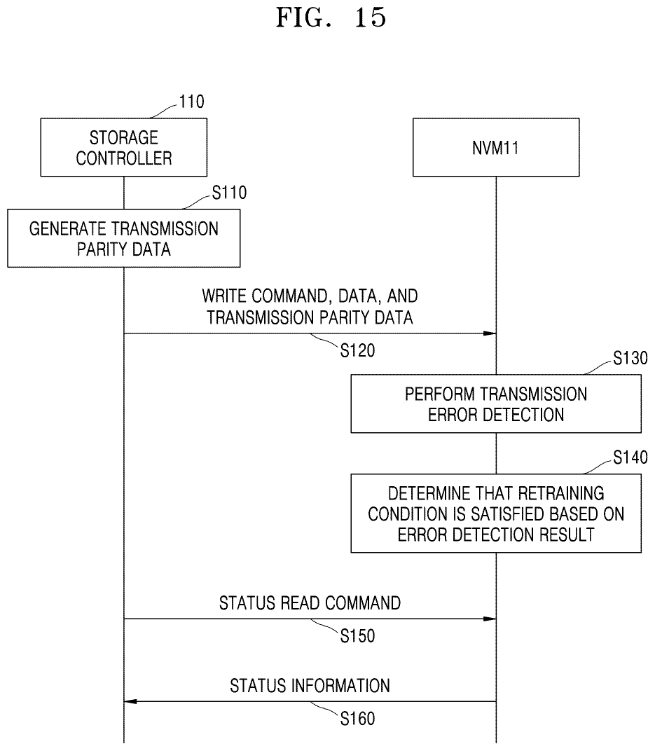

FIG. 15 is a flowchart of an example of operation of the storage device 100 of FIG. 1.

Referring to FIG. 15, the storage controller 110 may communicate with the non-volatile memory NVM 11 among a plurality of NVMs (e.g., NVM 11 to NVM mn in FIG. 2. The storage controller 110 may perform a write operation on the non-volatile memory NVM 11. The storage controller 110 may store data in the non-volatile memory NVM 11. For example, the storage controller 110 may perform a write operation on the non-volatile memory NVM 11 in response to a write request of an external host device.

Through a write operation, the storage controller 110 may determine whether retraining of the non-volatile memory NVM 11 is required. The storage controller 110 may determine whether to perform retraining of the non-volatile memory NVM 11 by performing a normal write operation without a separate monitoring operation (or polling operation). Alternatively, the storage controller 110 may determine whether to perform retraining of the non-volatile memory NVM 11 by performing a normal write operation together with a monitoring operation.

The storage controller 110 may generate transmission parity data in operation S110. The storage controller 110 may generate the transmission parity data based on data.

In an implementation, the storage controller 110 may divide the data into pieces by as many as the number of data lines. The storage controller 110 may divide the data into as many pieces of sub data as the number of data lines, wherein the pieces of sub data have the same size. For example, referring to FIG. 5, the storage controller 110 may divide the data into four pieces of sub data DATA_S0, DATA_S1, DATA_S2, and DATA_S3. The four pieces of sub data DATA_S0, DATA_S1, DATA_S2, and DATA_S3 may have the same size.

As described above with reference to FIG. 5, the transmission parity data may correspond to the first transmission parity data or the second transmission parity data. Here, the first transmission parity data may refer to parity data, which is used by an NVM to count the number of error bits resulting from transmission errors on a given data line. The second transmission parity data may refer to parity data, which is used by an NVM to determine whether there is a transmission error on a given data line. For example, the first transmission parity data may correspond to parity data (or parity bits) corresponding to the codeword described above with reference to FIGS. 8 to 14. For example, the second transmission parity data may correspond to a CRC value of transmitted data.

In an implementation, the storage controller 110 may generate the first transmission parity data corresponding to sub data for each data line. Referring to (a) of FIG. 5, the storage controller 110 may generate four pieces of first transmission parity data TP1_S0, TP1_S1, TP1_S2, and TP1_S3 respectively corresponding to the four pieces of sub data DATA_S0, DATA_S1, DATA_S2, and DATA_S3.

In some implementations, the storage controller 110 may generate the first transmission parity data corresponding to sub data for a first group of data lines and the second transmission parity data corresponding to sub data for a second group of data lines. Referring to (b) of FIG. 5, the storage controller 110 may generate two pieces of first transmission parity data TP1_S0 and TP1_S2 respectively corresponding to two pieces of sub data DATA_S0 and DATA_S2 to be transmitted respectively through two data lines DQ[0] and DQ[2] in the first group and may generate two pieces of second transmission parity data TP2_S1 and TP2_S3 respectively corresponding to two pieces of sub data DATA_S1 and DATA_S3 to be transmitted respectively through two data lines DQ[1] and DQ[3] in the second group.

The storage controller 110 may transmit a write command, the data, and the transmission parity data to the non-volatile memory NVM 11 in operation S120. The data may correspond to the write command. For example, the data may correspond to user data.

In an implementation, the storage controller 110 may transmit sub data and first transmission parity data corresponding to the sub data through each data line. Referring to (a) of FIG. 5, for example, the storage controller 110 may transmit, to the non-volatile memory NVM 11, the four pieces of sub data DATA_S0, DATA_S1, DATA_S2, and DATA_S3 and the four pieces of first transmission parity data TP1_S0, TP1_S1, TP1_S2, and TP1_S3 respectively corresponding to the four pieces of sub data DATA_S0, DATA_S1, DATA_S2, and DATA_S3 through the four data lines DQ[0], DQ[1], DQ[2], and DQ[4].

In some implementations, the storage controller 110 may transmit sub data and first transmission parity data corresponding to the sub data through data lines in a first group and may transmit sub data and second transmission parity data corresponding to the sub data through data lines in a second group. Referring to (b) of FIG. 5, the storage controller 110 may transmit, to the non-volatile memory NVM 11, the two pieces of sub data DATA_S0 and DATA_S2 and the two pieces of first transmission parity data TP1_S0 and TP1_S2 respectively corresponding to the two pieces of sub data DATA_S0 and DATA_S2 through the two data lines DQ[0] and DQ[2] in the first group. The storage controller 110 may transmit, to the NVM, the two pieces of sub data DATA_S1 and DATA_S3 and the two pieces of second transmission parity data TP2_S1 and TP2_S3 respectively corresponding to the two pieces of sub data DATA_S1 and DATA_S3 through the two data lines DQ[1] and DQ[3] in the second group.

The non-volatile memory NVM 11 may receive sub data and transmission parity data corresponding to the sub data through a plurality of data lines.

In an implementation, the non-volatile memory NVM 11 may receive sub data and first transmission parity data corresponding to the sub data through each data line. Referring to (a) of FIG. 5, for example, the non-volatile memory NVM 11 may receive the four pieces of sub data DATA_S0, DATA_S1, DATA_S2, and DATA_S3 and the four pieces of first transmission parity data TP1_S0, TP1_S1, TP1_S2, and TP1_S3 respectively corresponding to the four pieces of sub data DATA_S0, DATA_S1, DATA_S2, and DATA_S3 through the four data lines DQ[0], DQ[1], DQ[2], and DQ[4].

In some implementations, the non-volatile memory NVM 11 may receive sub data and first transmission parity data corresponding to the sub data through data lines in a first group and may receive sub data and second transmission parity data corresponding to the sub data through data lines in a second group. Referring to (b) of FIG. 5, the non-volatile memory NVM 11 may receive the two pieces of sub data DATA_S0 and DATA_S2 and the two pieces of first transmission parity data TP1_S0 and TP1_S2 respectively corresponding to the two pieces of sub data DATA_S0 and DATA_S2 through the two data lines DQ[0] and DQ[2] in the first group. The non-volatile memory NVM 11 may receive the two pieces of sub data DATA_S1 and DATA_S3 and the two pieces of second transmission parity data TP2_S1 and TP2_S3 respectively corresponding to the two pieces of sub data DATA_S1 and DATA_S3 through the two data lines DQ[1] and DQ[3] in the second group.

Due to the skew between a signal of a data line DQ and a signal of the data strobe line DQS, data received by the NVM may include an error. In other words, due to a transmission error, data transmitted by the storage controller 110 may be different from data received by the non-volatile memory NVM 11.

The non-volatile memory NVM 11 may perform transmission error detection in operation S130. The non-volatile memory NVM 11 may detect an error in data, based on transmission parity data. For example, the non-volatile memory NVM 11 (e.g., each of the 1^{st}-1 to 1^{st}-M decoders 10-1 to 10-M in FIG. 6 or 7) may count the number of transmission error bits with respect to a data line, based on the first transmission parity data. For example, the non-volatile memory NVM 11 (e.g., each of the 2^{nd}-1 to 2^{nd}-N decoders 20-1 to 20-N in FIG. 7) may determine existence or non-existence of a transmission error with respect to a data line, based on the second transmission parity data.

Based on a result of the transmission error detection, the non-volatile memory NVM 11 may determine whether a condition for performing retraining is satisfied in operation S140. For example, the retraining decision circuit 122 in FIG. 6 or 7 may determine whether a condition for performing retraining is satisfied, based on the result of the transmission error detection.

In an implementation, the transmission parity data may correspond to the first transmission parity data. The non-volatile memory NVM 11 may count the number of transmission error bits with respect to each of a plurality of data lines, based on each of a plurality of pieces of first transmission parity data. The non-volatile memory NVM 11 may determine whether a condition for performing retraining is satisfied, based on a counting result generated by the counting operation.

In some implementations, the transmission parity data may correspond to the second transmission parity data. The non-volatile memory NVM 11 may determine existence or non-existence of a transmission error with respect to each of a plurality of data lines, based on each of a plurality of pieces of second transmission parity data. The non-volatile memory NVM 11 may determine whether a condition for performing retraining is satisfied, based on a determination result generated by the determination operation.

In some implementations, the transmission parity data may include the first transmission parity data and the second transmission parity data. In other words, a first group of pieces of transmission parity data may correspond to the first transmission parity data, and a second group of pieces of transmission parity data may correspond to the second transmission parity data. In this case, the first group of data lines may transmit the first transmission parity data corresponding to the first group from the storage controller 110 to the non-volatile memory NVM 11, and the second group of data lines may transmit the second transmission parity data corresponding to the second group from the storage controller 110 to the non-volatile memory NVM 11. The non-volatile memory NVM 11 may count the number of transmission error bits on each of the data lines in the first group, based on the first transmission parity data. The non-volatile memory NVM 11 may determine whether there is a transmission error on each of the data lines in the second group, based on the second transmission parity data. The non-volatile memory NVM 11 may determine whether a condition for performing retraining is satisfied, based on a counting result generated from the counting operation and a determination result generated from the determination operation.

When the non-volatile memory NVM 11 determines that retraining is not required, based on a result of transmission error detection, the non-volatile memory NVM 11 may perform a write operation of received data.

When the non-volatile memory NVM 11 determines that retraining is required, based on a result of transmission error detection, the non-volatile memory NVM 11 may provide transmission error status information to the storage controller 110. Here, the transmission error status information may refer to information about an error that has occurred during data transmission through a data line and may include whether to perform retraining on all the data lines, whether to perform retraining on each of the data lines, or the number of transmission error bits on each data line. In this case, the non-volatile memory NVM 11 may not perform a write operation on the received data.

According to an implementation, the storage controller 110 may transmit a status read command to the non-volatile memory NVM 11. The non-volatile memory NVM 11 may transmit a response to the storage controller 110 in operation S160. The non-volatile memory NVM 11 may transmit transmission error status information (or a response to the status read command) to the storage controller 110.

In an implementation, the retraining decision circuit 122 may transmit a decision result about retraining to the control logic circuit 128. In an implementation, the control logic circuit 128 may generate a response to a status read command, based on the decision result about retraining. For example, the response to the status read command may include a transmission error field. The transmission error field may indicate whether there is a transmission error to the extent that retraining is required.

In an implementation, the retraining decision circuit 122 may generate transmission error status information based on the decision result about retraining. Through the transmission error status information, the non-volatile memory NVM 11 may notify the storage controller 110 that retraining is required. When the non-volatile memory NVM 11 determines that a retraining condition is satisfied, the non-volatile memory NVM 11 may transmit the transmission error status information to the storage controller 110. When the non-volatile memory NVM 11 determines that a retraining condition is not satisfied, the non-volatile memory NVM 11 may transmit the transmission error status information indicating a normal state (or a no-error state) to the storage controller 110.

The storage controller 110 may perform retraining of the non-volatile memory NVM 11 in response to the transmission error status information. The storage controller 110 may determine whether to perform retraining, based on the transmission error status information.

In an implementation, the storage controller 110 may perform retraining of only the non-volatile memory NVM 11 among the non-volatile memories NVM 11 to NVM mn. However, the scope of the present disclosure is not limited thereto. In an implementation, the storage controller 110 may perform retraining of the non-volatile memories NVM 11 to NVM In sharing the channel CH1. Alternatively, the storage controller 110 may perform retraining of all the non-volatile memories NVM 11 to NVM mn.

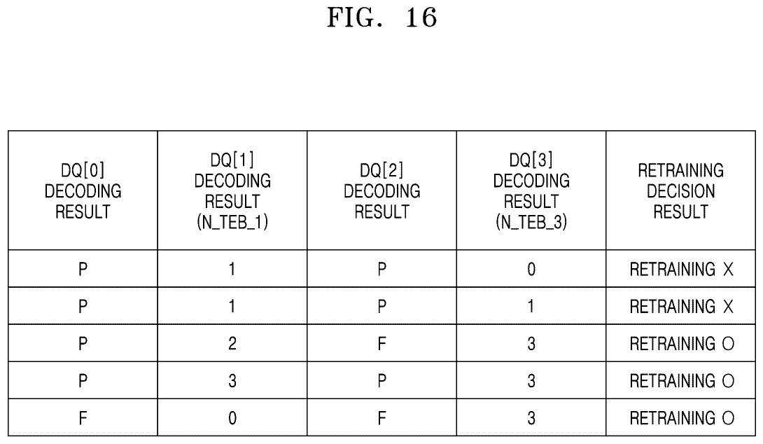

FIG. 16 shows examples of a condition for performing retraining, according to an implementation.

As described above with reference to FIG. 15, the non-volatile memory NVM 11 may determine whether a condition for performing retraining is satisfied, based on the transmission error detection result, in operation S140. For example, the retraining decision circuit 122 in FIG. 6 or 7 may determine whether a condition for performing retraining is satisfied, based on the transmission error detection result.

It may be assumed as in (b) of FIG. 5 that the second transmission parity data is applied to the two data lines DQ[0] and DQ[2], the first transmission parity data is applied to the two data lines DQ[1] and DQ[3], and whether to retrain all the data lines DQ[1] to DQ[4] is determined.

The non-volatile memory NVM 11 may decode received data based on the first transmission parity data or the second transmission parity data with respect to each data line. The non-volatile memory NVM 11 may determine whether to perform retraining, based on a decoding result.

FIG. 16 shows the decoding result with respect to each of the four data lines DQ[0], DQ[1], DQ[2], and DQ[3].

Referring to FIG. 16, a condition for performing retraining may be that a decoding result (i.e., a counting result) with respect to the first transmission parity data is at least 3 or that at least one decoding result with respect to the second transmission parity data is F. However, the present disclosure is not limited thereto. According to an implementation, retraining conditions (i.e., threshold conditions) may be variously combined.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An operating method of a storage device including a storage controller and a non-volatile memory, the operating method comprising:
generating, by the storage controller, a plurality of pieces of transmission parity data respectively corresponding to a plurality of data lines, the plurality of pieces of transmission parity data including first transmission parity data and second transmission parity data;
transmitting, by the storage controller and to the non-volatile memory, (i) a plurality of pieces of data respectively corresponding to the plurality of data lines and (ii) the plurality of pieces of transmission parity data respectively corresponding to the plurality of pieces of data, the first transmission parity data being transmitted through a first group of data lines of the plurality of data lines, and the second transmission parity data being transmitted through a second group of data lines of the plurality of data lines;
performing, by the non-volatile memory, a counting operation to count a number of transmission error bits with respect to each data line in the first group of data lines based on the first transmission parity data;
performing, by the non-volatile memory, a determination operation to determine that a transmission error exists with respect to each data line in the second group of data lines based on the second transmission parity data;
determining, by the non-volatile memory, that a condition for performing retraining is satisfied based on a counting result generated from the counting operation and a determination result generated from the determination operation; and
transmitting, by the non-volatile memory, transmission error status information to the storage controller based on a determination that the condition for performing retraining is satisfied.

2. The operating method of claim 1, wherein the first transmission parity data is generated by the storage controller based on shortened Hamming code encoding.

3. The operating method of claim 2, wherein the first transmission parity data includes a bit making a number of 1s in the first transmission parity data an even number.

4. The operating method of claim 1, wherein the first transmission parity data is generated by the storage controller based on shortened Bose-Chaudhuri-Hocquenghem (BCH) code encoding.

5. The operating method of claim 4, wherein the first transmission parity data includes a bit making a number of 1s in the first transmission parity data an even number.

6. The operating method of claim 1, wherein
the transmission error status information includes:
an index of a data line of the plurality of data lines that has a transmission error; and
a number of transmission errors counted with respect to the data line.

7. The operating method of claim 1, wherein
the transmission error status information includes a transmission error status or the number of transmission error bits with respect to each of the plurality of data lines.

8. An operating method of a non-volatile memory, the operating method comprising:
receiving, from a storage controller, (i) a plurality of pieces of data respectively corresponding to a plurality of data lines and (ii) a plurality of pieces of transmission parity data respectively corresponding to the plurality of pieces of data;
performing a counting operation to count a number of transmission error bits with respect to each of the plurality of data lines based on the transmission parity data;
determining that a condition for performing retraining is satisfied based on a counting result generated from the counting operation; and
transmitting transmission error status information to the storage controller based on a determination that the condition for performing retraining is satisfied.

9. The operating method of claim 8, wherein the transmission parity data is generated by the storage controller based on shortened Hamming code encoding.

10. The operating method of claim 9, wherein the transmission parity data includes a bit making a number of 1s in the transmission parity data an even number.

11. The operating method of claim 8, wherein the transmission parity data is generated by the storage controller based on shortened Bose-Chaudhuri-Hocquenghem (BCH) code encoding.

12. The operating method of claim 11, wherein the transmission parity data includes a bit making a number of 1s in the transmission parity data an even number.

13. The operating method of claim 8, wherein
the transmission error status information includes:
an index of a data line of the plurality of data lines that has a transmission error; and
a number of transmission errors counted with respect to the data line.

14. The operating method of claim 8, wherein
the transmission error status information includes a transmission error status or the number of transmission error bits with respect to each of the plurality of data lines.

15. A storage device comprising:
a non-volatile memory; and
a storage controller configured to generate a plurality of pieces of transmission parity data respectively corresponding to a plurality of data lines and transmit, to the non-volatile memory, (i) a plurality of pieces of data respectively corresponding to the plurality of data lines and (ii) the plurality of pieces of transmission parity data respectively corresponding to the plurality of pieces of data,
wherein the non-volatile memory is configured to
perform a counting operation to count a number of transmission error bits with respect to each of the plurality of data lines based on the transmission parity data,
determine that a condition for performing retraining is satisfied based on a counting result generated from the counting operation, and
transmit transmission error status information to the storage controller based on a determination that the condition for performing retraining is satisfied.

16. The storage device of claim 15, wherein the transmission parity data is generated by the storage controller based on shortened Hamming code encoding.

17. The storage device of claim 16, wherein the transmission parity data includes a bit making a number of 1s in the transmission parity data an even number.

18. The storage device of claim 15, wherein the transmission parity data is generated by the storage controller based on shortened Bose-Chaudhuri-Hocquenghem (BCH) code encoding.

19. The storage device of claim 15, wherein the transmission parity data is generated by the storage controller based on single-parity-checker (SPC) encoding.

20. The storage device of claim 15, wherein
the transmission error status information includes:
an index of a data line of the plurality of data lines that has a transmission error; and
a number of transmission errors counted with respect to the data line.
